(19) United States
(12) Patent Application Publication
(10) Pub. No.: US 2010/0071828 A1
(43) Pub. Date: Mar. 25, 2010

(54) METHOD OF PRODUCING MULTILAYER STRUCTURE

(75) Inventor: Hiroshi SATO, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/542,730

(22) Filed: Aug. 18, 2009

(30) Foreign Application Priority Data
Sep. 24, 2008 (JP) 2008-244417

(51) Int. Cl. B32B 37/12; C23C 14/34; C25D 5/00; B05D 1/36; B29C 45/14

(52) U.S. Cl. 156/60; 204/192.1; 205/80; 427/404; 264/259

(57) ABSTRACT

A method of producing a multilayer structure including a substrate, an adhesive layer and a metal layer, the method including: forming the adhesive layer on the substrate or a metal foil that forms the metal layer by applying a composition containing an acrylic resin having a repeating unit that is derived from an ethylenic unsaturated monomer having a divalent sulfur atom, and applying energy to the composition; and (if the adhesive layer is formed on the substrate) forming the metal layer on the adhesive layer by laminating a metal foil or forming a metal film by evaporation or sputtering, or (if the adhesive layer is formed on the metal foil) forming an organic resin layer that forms the substrate on the adhesive layer by a casting method.

### CROSS-REFERENCE TO RELATED APPLICATION

This application claims priority under 35 USC 119 from Japanese Patent Application No. 2008-244417 filed on Sep. 24, 2008, the disclosure of which is incorporated by reference herein.

### BACKGROUND OF THE INVENTION

1. Field of the Invention

The present invention relates to a method of producing a multilayer structure.

2. Description of the Related Art

Conventionally, there have been two major methods of forming a metal pattern, i.e., a subtractive method and a semi-additive method, as a method of forming a conductive pattern.

The subtractive method is a technique including forming a metal layer on a substrate, forming a photosensitive layer that is sensitive to actinic rays on the metal layer, exposing the photosensitive layer to light in an image-wise manner, forming a resist image by developing the photosensitive layer, forming a conductive pattern by etching the metal, and then removing the resist image. In this method, the substrate is subjected to a surface roughening treatment so that the substrate can be tightly adhered to the metal layer by an anchoring effect. As a result, there is a problem in applications for electronic circuit in that high-frequency characteristics of the obtained conductive pattern may deteriorate due to the roughened surface of the substrate to which the conductive pattern is adhered.

On the other hand, in the semi-additive method, a thin primer metal layer of Cr or the like is formed on the substrate by plating or the like, and then a resist pattern is formed on the primer metal layer. Subsequently, a metal layer of Cu or the like is formed on a portion of the primer metal layer other than the resist pattern by plating or the like, and the resist pattern is removed to form a wiring pattern. Then, the primer metal layer is etched using the wiring pattern as a mask, thereby forming a conductive pattern only on the portion other than the resist pattern. This method is advantageous in terms of environmental suitability and production cost, since a fine pattern of 30 μm or less can be easily formed and metal is deposited by plating only on a necessary portion. However, even in this method, the substrate needs to be subjected to a surface roughening treatment so that the conductive pattern can be tightly adhered to the substrate. As a result, there is a problem in applications for electronic circuit in that high-frequency characteristics of the conductive pattern may deteriorate due to the roughened surface of the substrate to which the conductive pattern is adhered.

Therefore, there is a demand for a technique of forming a wiring that can tightly adhere to a substrate having a smooth surface.

In order to address the above problems, there is a technique of adhering a pattern to the substrate by means of sulfur, which has a high affinity to a metal.

For example, Japanese Patent Application Laid-Open (JP-A) No. 7-314603 proposes a method of using a crosslinked adhesive containing a sulfur component (vulcanizing agent); JP-A No. 8-148829 proposes a method of using a thermosetting undercoating agent containing a sulfur-containing epoxy resin; JP-A No. 8-148830 proposes a method of using a thermosetting undercoating agent containing a sulfur-containing curing agent; JP-A No. 10-178035 proposes a method of using a thermal stress relaxation effect of an adhesive composition containing a resin having a specific structure including a sulfide bond and a thermosetting resin; JP-A No. 2000-196207 proposes a method of treating a copper foil with polythiol; JP-A No. 2001-298275 proposes a method of using an interlayer insulating film composed of a layer formed from a specific resin and a layer formed from a compound containing an aromatic ring and an atom selected from oxygen, nitrogen and sulfur; JP-A No. 2003-167331 proposes a method of using an episulfide-containing resin composition as an adhesive composition; JP-A No. 2007-39486 proposes a method of using a resin composition containing a specific disulfide compound or thioether compound as an adhesive composition; JP-A No. 2007-128864 proposes a method of using a fluid composition containing a hydrophilic sulfur compound, nitrogen compound or phosphorous compound and a crosslinking agent; and JP-A No. 2008-50541 proposes a method of using a silane coupling agent containing mercaptotriazine as a molecular adhesive.

Further, a sputtering method (a metalizing method by plating), which is a common technique of producing a flexible printed circuit board, may be used for forming a metal layer that is highly adhesive to a smooth substrate surface. Additionally, a technique of creating adhesiveness by way of a plating method other than sputtering has also been proposed in recent years (for example, JP-A Nos. 2004-79660 and 2004-186661).

However, in the techniques described in the above documents (except JP-A No. 2008-50541), annealing needs to be conducted at a temperature of as high as 150 to 190° C., which is not applicable to the field of organic electronics or the like, in which a device such as TFT is formed on a film substrate desirably through a low-temperature process.

Moreover, in the techniques described in JP-A Nos. 2008-50541, 2004-79660 and 2004-186661, since the surface of the substrate needs to be hydrophilized as a pre-treatment, electrical insulating properties between the metal patterns formed on the substrate may be inferior. Further, since chromium sputtering is performed to form a seeding layer, there may be a great effect on environment and sufficient adhesiveness may not be achieved.

In view of the above circumstances, there is a demand for a method of forming a metal layer that is highly adhesive to a smooth substrate in a low-temperature process, namely, at a process temperature of 90° C. or less. Moreover, in terms of electrical insulating properties between the metal patterns, the metal layer is preferably formed on the substrate without subjecting its surface to a hydrophilizing pre-treatment. Further, it is preferable if the metal layer can be formed by a chromium-free process in terms of environmental concerns also.

### SUMMARY OF THE INVENTION

A first aspect of the invention provides a method of producing a multilayer structure including a substrate, an adhesive layer and a metal layer, the method comprising:

(a1) forming the adhesive layer on the substrate by applying a composition to the substrate, the composition comprising an acrylic resin having a repeating unit that is derived from an ethylenic unsaturated monomer having a divalent sulfur atom, and applying energy to the composition; and

(b1) forming the metal layer on the adhesive layer by laminating a metal foil or by forming a metal film by evaporation or sputtering.

A second aspect of the invention provides a method of producing a multilayer structure including a substrate, an adhesive layer and a metal layer, the method comprising:

(a2) forming the adhesive layer on a metal foil that forms the metal layer by applying a composition to the metal foil, the composition comprising an acrylic resin having a repeating unit that is derived from an ethylenic unsaturated monomer having a divalent sulfur atom, and applying energy to the composition; and

(b2) forming the substrate on the adhesive layer by forming a film of an organic resin by a casting method.

### BRIEF DESCRIPTION OF THE DRAWING

FIG. 1 is a plan view of the shape of the comb-shaped pattern used for evaluating insulating properties that is prepared in the Examples and Comparative Examples.

### DETAILED DESCRIPTION OF THE INVENTION

In the following, details of each step of the first aspect of the method of producing a multilayer structure (method of producing a multilayer structure <1>, hereinafter) and the second aspect of the method of producing a multilayer structure (method of producing a multilayer structure 2, hereinafter) will be described.

Step (a1)

In step (a1) of the method of producing a multilayer structure <1>, an adhesive layer is formed on a substrate by applying a composition to s substrate, the composition containing an acrylic resin having a repeating unit that is derived from an ethylenic unsaturated monomer having a divalent sulfur atom, and then applying energy to the composition.

<Substrate>

The substrate used in step (a1) is described. The substrate used in the invention is preferably selected from a metal substrate, an organic resin substrate, or an organic resin substrate onto which a metal is laminated. The metal is preferably one that is less adhesive, such as silver, copper or gold. The metal may be layered on an organic resin substrate, which may be in a patterned shape.

The organic resin that may be used in the invention is not particularly limited, but may be selected from the following exemplary resins.

Epoxy resin, polyimide resin, PET, PEN, cellulose triacetate, polyethylene, polystyrene, polypropylene, polycarbonate, polyvinyl acetal, polytetrafluoroethylene, cycloolefin polymer, polyphenylene ether, polyphenylene oxide, liquid crystal polymer, benzocyclobutene resin, polyether sulfone, polyether imide, polyarylate, aramid resin, phenol resin, bismaleimide triazine resin, cyanate resin, and ABS resin.

The substrate is typically flat-shaped. However, the substrate is not particularly limited thereto and may have a cylindrical shape or the like.

The method of the invention may be particularly effectively applied to a multilayer structure having an organic resin substrate, since the method is suitable for low-temperature processing. The organic resin substrate here refers to a substrate that is at least partly formed from an organic resin, and examples thereof include a composite organic substrate including plural organic resin layers or a substrate including an organic resin layer formed on an inorganic support such as glass.

Organic resins that are suitable for low-temperature processing include epoxy resin, polyimide resin, polyester resin, polycarbonate resin and ABS resin.

Further, the substrate may include a compound capable of generating photo-radicals or a compound capable of causing radical reaction, in order to improve its adhesiveness to the adhesive layer.

<Adhesive Layer>

The composition for forming the adhesive layer in step (a1) and the adhesive layer formed from the composition are described.

First, an acrylic resin containing a repeating unit that is derived from an ethylenic unsaturated monomer having a divalent sulfur atom (hereinafter, referred to “sulfur atom-containing acrylic resin” sometimes) is described.

(Sulfur-Containing Acrylic Resin)

The sulfur-containing acrylic resin used in the invention includes a repeating unit that is derived from an ethylenic unsaturated monomer having a divalent sulfur atom. The ethylenic unsaturated monomer having a divalent sulfur atom is not particularly limited as long as it has at least a divalent sulfur atom and at least one ethylenic unsaturated bond of an acryloyl group or a methacryloyl group.

Specific examples of the ethylenic unsaturated monomer having a divalent sulfur atom are described in paragraph [0007] of JP-A No. 9-110827; pages 14 to 16 of Japanese National Publication No. 2000-509075; paragraphs [0053] to [0068] of JP-A No. 2007-114433; and paragraphs [0087] to [0095] of JP-A No. 2007-314599.

Preferred examples of the ethylenic unsaturated monomer having a divalent sulfur atom include an ethylenic unsaturated monomer having, as a sulfur component, a linear sulfide group, a thiocarbonate group, a sulfur-containing heterocyclic group such as a cyclic sulfide group, a benzothiazole group, or a thiouracil group.

In the invention, the repeating unit that is derived from an ethylenic unsaturated monomer having a divalent sulfur atom is preferably a repeating unit represented by the following Formula (1).

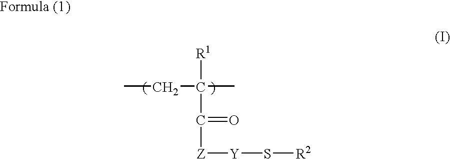

In Formula (1), R¹ represents a hydrogen atom or an alkyl group having 1 to 4 carbon atoms. Examples of the alkyl group having 1 to 4 carbon atoms include a methyl group, an ethyl group, an n-propyl group, an i-propyl group, an n-butyl group, a sec-butyl group, an i-butyl group, and a tert-butyl group. Among these, a methyl group is preferred.

In formula (1), R² represents a hydrogen group, an alkyl group having 1 to 18 carbon atoms, an aryl group having 6 to 14 carbon atoms, or an arylalkyl group having 7 to 16 group. These groups may be substituted or not, and may have a saturated or unsaturated cyclic structure.

Examples of the substituent for the alkyl group having 1 to 18 carbon atoms represented by R² include an alkyl group such as a methyl group, an ethyl group, an n-propyl group, an i-propyl group, an n-butyl group, a sec-butyl group, an i-butyl group, a tert-butyl group, a hexyl group, an octyl group, a dodecyl group, and a stearyl group. When these alkyl groups have a substituent, preferred examples thereof include a halogen atom, a hydroxyl group, an amino group, an amide group, a carboxyl group, an ester group, and a sulfonyl group.

The alkyl group is preferably an alkyl group having 1 to 12 carbon atoms, more preferably an alkyl group having 1 to 8 carbon atoms, and particularly preferably a methyl group, an ethyl group, an n-propyl group, an i-propyl group, an n-butyl group or a tert-butyl group.

The aryl group having 6 to 14 carbon atoms represented by R² may be substituted or not, and examples thereof include a phenyl group, a tolyl group, a xylyl group, a naphthyl group, and an anthryl group. The aryl group may have a substituent, and preferable examples thereof include a halogen atom, a hydroxyl group, an amino group, an amide group, a carboxyl group, an ester group, and a sulfonyl group.

The aryl group is preferably an aryl group having 6 to 10 carbon atoms, more preferably a phenyl group.

The arylalkyl group having 7 to 16 carbon atoms represented by R² may be substituted or not, and examples thereof include a benzyl group, a phenetyl group, a naphthyl methyl group, and an anthryl methyl group. The arylalkyl group may have a substituent, and preferable examples thereof include a halogen atom, a hydroxyl group, an amino group, an amide group, a carboxyl group, an ester group, and a sulfonyl group.

The arylalkyl group is preferably an aryl group having 7 to 11 carbon atoms, more preferably a benzyl group.

In Formula (1), Z represents —O— or —NH—. Y represents a divalent linking group having 1 to 8 carbon atoms.

The divalent linking group having 1 to 8 carbon atoms represented by Y is preferably an alkylene group (such as a methylene group, an ethylene group, a propylene group, a butylene group, and a pentylene group), an alkenylene group (such as an ethenylene group and a propenylene group), an alkynylene group (such as an ethynylene group and a propynylene group), an arylene group (such as a phenylene group), a divalent heterocyclic group (such as a 6-chloro-1,3,5-triazine-2,4-diyl group, a pyrimidine-2,4-dityl group, a quinoxyaline-2,3-diyl group, and a pyridazine-3,6-diyl group), —O—, —CO—, —NR— (R represents a hydrogen atom, an alkyl group or an aryl group), or a combination of these groups (such as —NHCH₂CH₂NH— and —NHCONH—).

The alkylene group, alkenylene group, alkynylene group, arylene group or divalent heterocyclic group represented by Y and the alkyl group or aryl group represented by R may have a substituent. Examples of the substituent include those for the aryl group represented by R². The alkyl group or aryl group represented by R have the same definitions as the alkyl group or aryl group represented by R².

The divalent linking group having 1 to 8 carbon atoms represented by Y is preferably a divalent linking group having 1 to 6 carbon atoms, more preferably an ethylene group, a propylene group, a butylene group, a hexylene group, —CH₂—CH(OH)—CH₂—, or —C₂H₄—O—C₂H₄—.

The following are specific examples of the repeating unit that is derived from an ethylenic unsaturated monomer having a divalent sulfur atom. However, the invention is not limited thereto.

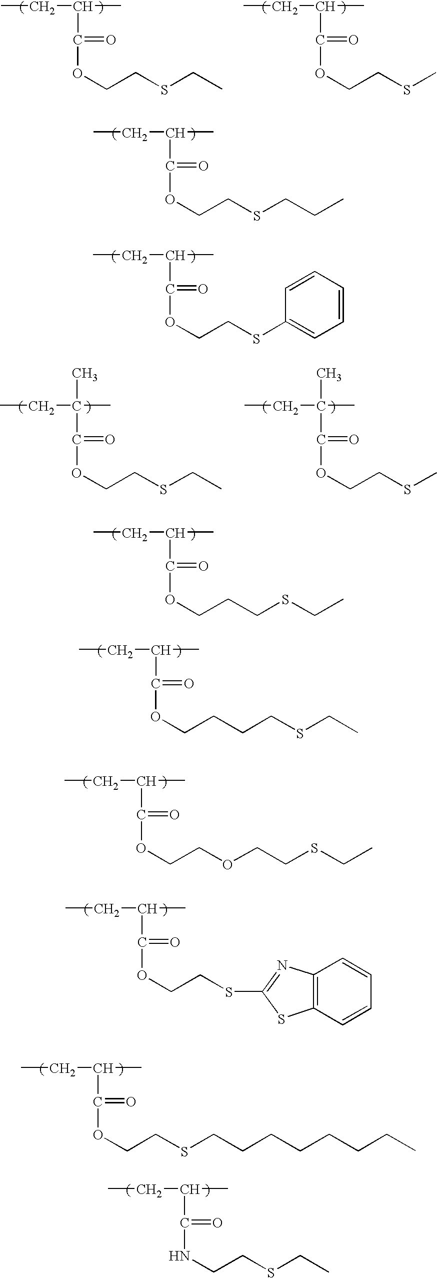

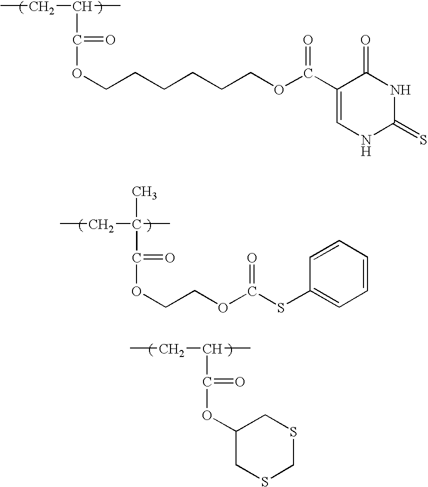

The sulfur atom-containing acrylic resin in the invention preferably includes a repeating unit as mentioned above at an amount of 1% to 100%, more preferably 5% to 80%, and particularly preferably 10% to 50%, in terms of mass fraction. When the mass fraction is within the above range, it is effective to exhibit high adhesiveness between the substrate and the metal film.

The sulfur atom-containing acrylic resin may have a component that cures by heat or light in the molecule. Examples of the component that cures by heat or light include an acryloyl group, a methacryloyl group, an oxirane group, an oxetane group, a vinylether group, and an allyl group. Among these, an acryloyl group and a methacryloyl group are preferable in view of synthesis suitability or cost.

The component that cures by heat or light is preferably introduced into the sulfur atom-containing acrylic resin in the form of a repeating unit as shown below. However, the invention is not limited thereto.

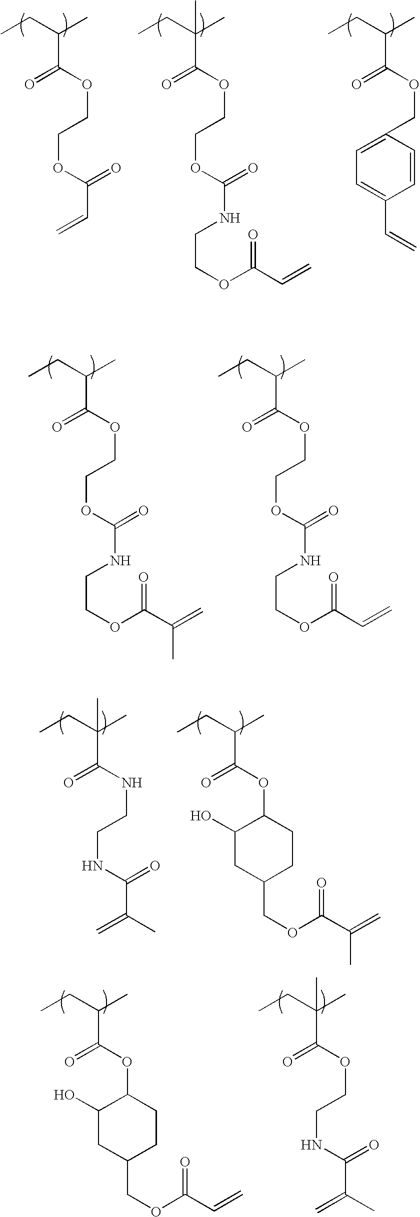

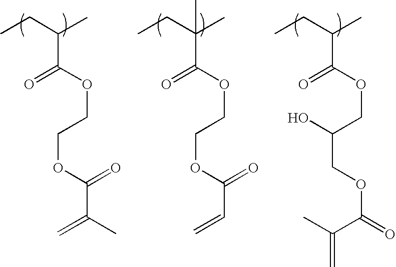

The sulfur atom-containing acrylic resin preferably includes a repeating unit having a component that cures by heat or light at an amount of 1 mol % to 99 mol %, more preferably 5 mol % to 50 mol %, and further preferably 10 mol % to 30 mol %.

Further, the sulfur atom-containing acrylic resin may have, as necessary, an acid group in the molecule in order to impart alkali developability to the resin. Examples of the acid group include a carboxyl group, a sulfonic group, a phosphoric group, a boronic acid group, a phenol group, and a sulfoamide group. Among these, a carboxyl group is particularly preferable.

The acid group may be introduced into the sulfur atom-containing acrylic resin in the form of a repeating unit as shown below. However, the invention is not limited thereto.

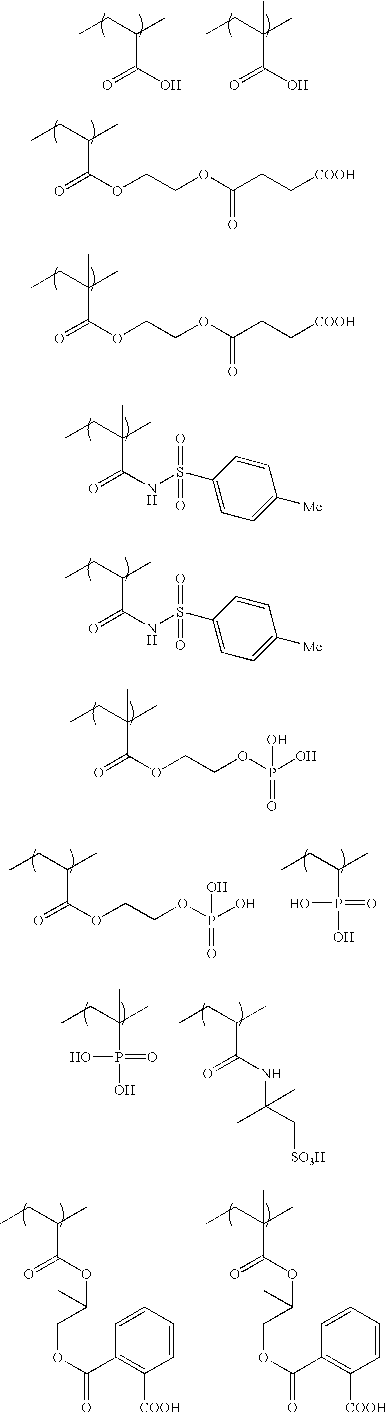

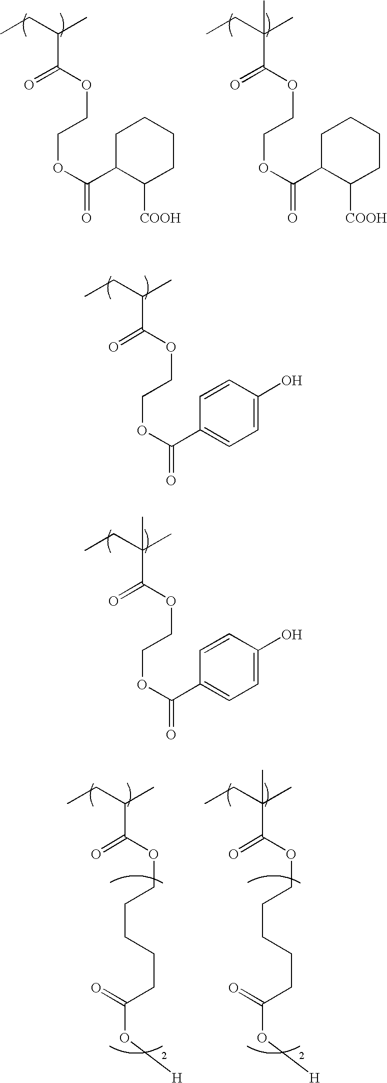

When alkali development is performed in step (a1), the sulfur atom-containing acrylic resin preferably has an acid value of 20 to 400 mgKOH/g, more preferably 50 to 350 mgKOH/g. When the acid value is within the above range, favorable alkali developability may be achieved.

The repeating unit having an acid group is preferably included in the sulfur atom-containing acrylic resin so as to satisfy the above range of acid value.

The weight average molecular weight of the sulfur atom-containing acrylic resin is preferably 2,000 to 1,000,000, more preferably 3,000 to 200,000, and most preferably 5,000 to 100,000. When the weight average molecular weight of the sulfur atom-containing acrylic resin is within the above range, adhesiveness between the substrate and the metal film may be effectively improved and damages on developability may be avoided.

(Compounds that Cures by Heat or Light)

The composition used in the invention preferably contains a compound that cures by heat or light. Examples of the compound that cures by heat or light include a polyfunctional monomer. The polyfunctional monomer may polymerize by itself and function as a binder in the adhesive layer. By including such a monomer, film strength of adhesive layer can be enhanced. The polyfunctional monomer is preferably a photopolymerizable monomer in view of a low-temperature processing suitability.

The polyfunctional monomers may be a compound having a boiling point at an ordinary pressure of 100° C. or more, and examples thereof include ethylene glycol(meth)acrylate, triethylene glycol di(meth)acrylate, tetramethylene glycol di(meth)acrylate, propylene glycol di(meth)acrylate, polyethylene glycol di(meth)acrylate, polypropylene glycol di(meth)acrylate, 1,3-butanediol di(meth)acrylate, trimethylol ethane triacrylate, trimethylol propane tri(meth)acrylate, trimethylol propane di(meth)acrylate, neopentyl glycol di(meth)acrylate, pentaerythritol tetra(meth)acrylate, pentaerythritol tri(meth)acrylate, pentaerythritol hexa(meth)acrylate, dipentaerythritol hexa(meth)acrylate, dipentaerythritol penta(meth)acrylate, 1,4-hexanediol (meth)acrylate, hexanediol di(meth)acrylate, trimethylol propane, tri(acryloyloxypropyl)ether, tri(acryloyloxyethyl)isocyanurate, tri(acryloyloxyethyl)cyanurate, glycerine tri(meth)acrylate, or a polyfunctional (meth)acrylate obtained by subjecting a polyfunctional alcohol such as trimethylolpropane or glycerin to addition reaction with ethylene oxide, propylene oxide or the like, and then (meth)acrylating the reactant.

Further examples include polyfunctional acrylates and methacrylates such as the urethane acrylates described in JP-A Nos. 48-41708, 50-6034 and 51-37193; the polyester acrylates described in JP-A Nos. 48-64183, 49-43191 and 52-30490; and epoxy acrylates formed by reacting an epoxy resin with (meth)acrylic acid.

Among these, polyfunctional acrylic monomer such as trimethylol propane (meth)acrylate, pentaerythritol tetra(meth)acrylate, dipentaerythritol hexa(meth)acrylate, and dipentaerythritol penta(meth)acrylate are preferable. The polyfunctional monomer may be used alone or in combination of two or more.

When a polyfunctional monomer is used, the amount thereof in the composition is not particularly limited, but is typically 5 to 50% by mass, preferably 10 to 40% by mass. When the amount is within the above range, favorable sensitivity to light or strength of the adhesive layer may be achieved, while avoiding the adhesive layer being excessively adhesive.

An oligomer may be also included in addition to the polyfunctional monomer.

(Polymerization Initiator)

The composition used in the invention preferably includes a polymerization initiator in order to enhance the curability by light or heat of the composition that contains a sulfur atom-containing acrylic resin having a component that cures by light or heat or a polyfunctional monomer, which are a compound that is curable by light or heat.

The polymerization initiator may be either a thermal-polymerization initiator or a photo-polymerization initiator. The photo-polymerization initiator is more preferably added to the composition so that the composition can be cured by light or heat.

The thermal-polymerization initiators that may be used in the composition include a peroxide initiator such as benzoyl peroxide and azobis isobutylonitrile, and an azo initiator.

The photo-polymerization initiators include: (a) aromatic ketones, (b) onium salt compounds, (c) organic peroxides, (d) thio compounds, (e) hexaarylbiimidazole compounds, (f) ketoxime ester compounds, (g) borate compounds, (h) azinium compounds, (i) active ester compounds, (j) carbon-halogen bond-containing compounds, and (k) pyridium compounds. The following are specific examples of the compounds (a) to (k), but the invention is not limited thereto.

(a) Aromatic Ketones

In the invention, preferable aromatic ketones include the compounds having a benzophenone skeleton or thioxanthone skeleton described in “Radiation Curing in Polymer Science and Technology”, J. P. Fouassier and J. F. Rabek, (1993), pp. 77-117.

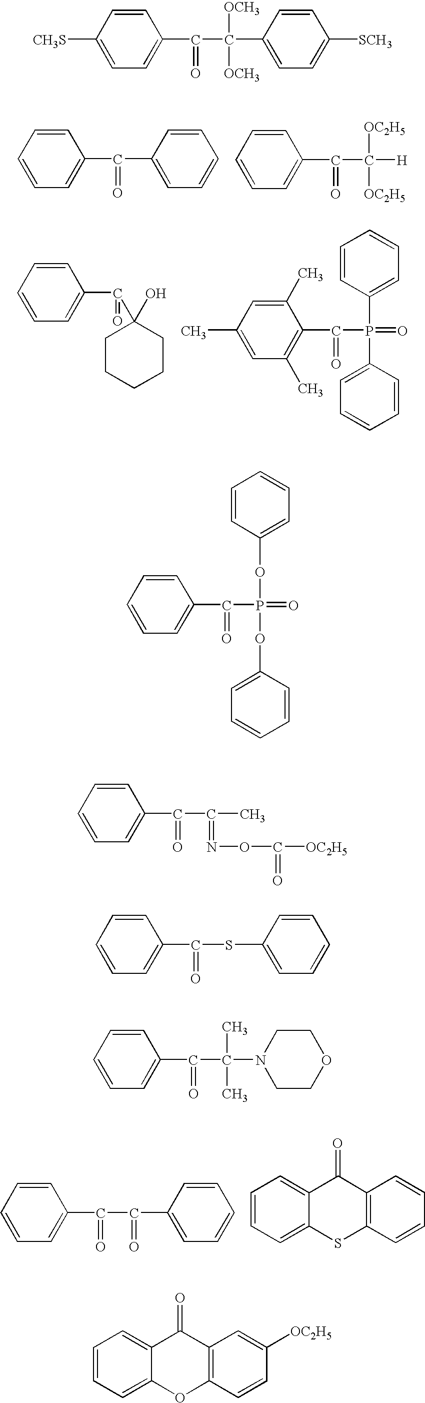

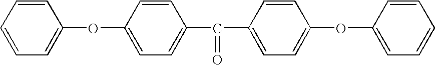

Among these, particularly preferable aromatic ketones are described below.

α-thiobenzophenone compounds described in Japanese Patent Publication (JP-B) No. 47-6416 and benzoin ether compounds described in JP-B No. 47-3981, such as the following compound.

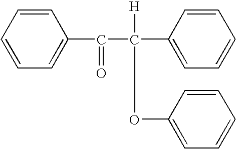

α-substituted benzoin compounds described in JP-B No. 47-22326, such as the following compound.

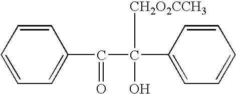

Benzoin derivatives described in JP-B No. 47-23664 and aroyl phosphates described in JP-A No. 57-30704 and dialkoxybenzophenones described in JP-A No. 60-26483, such as the following compound.

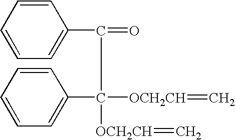

Benzoin ethers described in JP-B No. 60-26403 and JP-A No. 62-81345, such as the following compound.

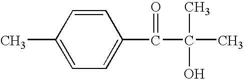

α-amino benzophenones described in JP-A No. 1-34242, U.S. Pat. No. 4,318,791 and European Patent No. 284561A1, such as the following compounds.

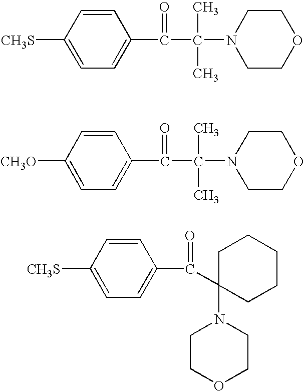

p-di(dimethylaminobenzoyl)benzenes described in JP-A No. 2-211452, such as the following compound.

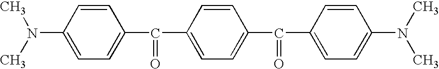

Thio-substituted aromatic ketones described in JP-A No. 61-194062, such as the following compound.

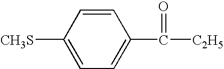

Acylphosphine sulfides described in JP-B No. 2-9597, such as the following compounds.

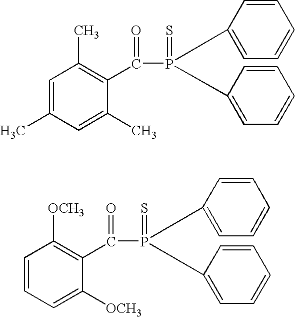

Acylphosphines described in JP-B No. 2-9596, such as the following compounds.

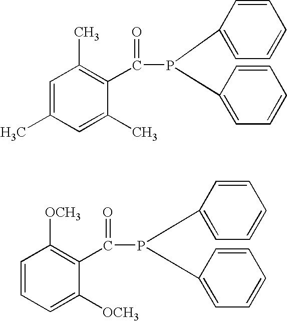

Further examples include thioxanthones described in JP-B No. 63-61950 and coumarines described in JP-A No. 59-42864.

(b) Onium Salt Compounds

In the invention, examples of the onium salt compound that are suitably used as a photo-polymerization initiator include the compounds represented by the following Formulae (1) to (3).

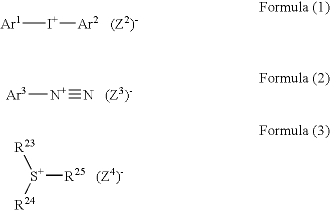

In Formula (1), Ar¹ and Ar² each independently represent an aryl group having carbon atoms of 20 or less that may have a substituent. When the aryl group has a substituent, preferable examples thereof include a halogen atom, a nitro group, an alkyl group having carbon atoms of 12 or less, an alkoxy group having carbon atoms of 12 or less, an aryloxy group having carbon atoms of 12 or less, and an aryloxy group having carbon atoms of 12 or less. (Z²)⁻ is a counter ion selected from the group consisting of a halogen ion, a perchlorate ion, a carboxylate ion, a tetrafluoroborate ion, a hexafluorophosphate ion, and a sulfonic acid ion. Among these, a perchlorate ion, a hezafluorophosphate ion and a sulfonic acid ion are preferable.

In Formula (2), Ar³ represents an aryl group having carbon atoms of 20 or less that may have a substituent. When the aryl group has a substituent, preferable examples thereof include a halogen atom, a nitro group, an alkyl group having carbon atoms of 12 or less, an alkoxy group having carbon atoms of 12 or less, an aryloxy group having carbon atoms of 12 or less, an alkylamino group having carbon atoms of 12 or less, a dialkylamino group having carbon atoms of 12 or less, an arylamino group having carbon atoms of 12 or less, and a diarylamino group having carbon atoms of 12 or less. (Z³)⁻ is a counter ion having the same definitions as (Z²)⁻.

In Formula (3), R²³, R²⁴ and R²⁵ each independently represent a hydrocarbon group having carbon atoms of 20 or less that may have a substituent. When the hydrocarbon group has a substituent, preferable examples thereof include a halogen atom, a nitro group, an alkyl group having carbon atoms of 12 or less, an alkoxy group having carbon atoms of 12 or less, and an aryloxy group having carbon atoms of 12 or less. (Z⁴)⁻ is a counter ion having the same definitions as (Z²)⁻.

Specific examples of the onium salt compound that may be suitably used in the invention include those described in paragraphs [0030] to [0033] of JP-A No. 2001-133969, paragraphs [0048] to [0052] of JP-A No. 2001-305734 and paragraphs [0015] to [0046] of JP-A No. 2001-343742.

(c) Organic Peroxides

In the invention, the organic peroxides having a structure capable of initiating photo-polymerization include almost all organic compounds having one or more oxygen-oxygen bonds in the molecule. Examples thereof include methyl ethyl ketone peroxide, cyclohexanone peroxide, acetylacetone peroxide, 1,1,3,3-tetramethyl butyl hydroperoxide, ditertiary butyl peroxide, tertiary butyl peroxylaurate, tertiary butyl peroxy carbonate, 3,3′,4,4′-tetra-(t-butyl peroxycarbonyl)benzophenone, 3,3′,4,4′-tetra-(t-amylperoxycarbonyl)benzophenone, 3,3′,4,4′-tetra(t-hexyl peroxycarbonyl)benzophenone, 3,3′,4,4′-tetra(t-octyl peroxycarbonyl)benzophenone, 3,3′,4,4′-tetra(cumyl peroxycarbonyl)benzophenone, 3,3′,4,4′-tetra(p-isopropylcumyl peroxycarbonyl)benzophenone, carbonyl di(t-butylperoxy dihydrogen diphthalate), and carbonyl di(t-hexylperoxy dihydrogen diphthaltate).

(d) Thio Compounds

In the invention, the thio compounds that may be suitably used as a photo-polymerization initiator include the compound having a structure represented by the following Formula (4).

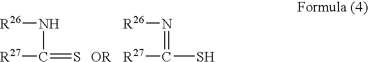

In Formula (4), R²⁶ represents an alkyl group, an aryl group or a substituted aryl group, and R²⁷ represents a hydrogen atom or an alkyl group. R²⁶ and R²⁷ are non-metallic atom group that may bond together to form a 5 to 7-membered ring that may include a hetero atom selected from oxygen, sulfur or nitrogen.

Specific examples of the thio compound represented by Formula (4) include compounds having a functional group shown in the following Table 1.

TABLE 1

| No. | R²⁶ | R²⁷ |
|---|---|---|
| 1 | —H | —H |
| 2 | —H | —CH₃ |
| 3 | —C₆H₅ | —C₂H₅ |
| 4 | —C₆H₄—CH₃ | —C₄H₉ |
| 5 | —C₆H₄—OCH₃ | —CH₃ |

| | |
|---|---|
| 6 | —(CH₂)₂— |
| 7 | —CH(CH₃)—CH₂—S— |

(e) Hexaryl Biimidazole Compounds

In the invention, the hexaryl biimicazole compound that may be suitably used as a photo-polymerization initiator include lophine dimers described in JP-B No. 45-37377 and JP-B No. 44-86516, such as 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, and 2,2′-bis(o-trifluorophenyl)-4,4′,5,5′-tetraphenylbiimidazole.

(f) Ketoxime Ester Compounds

In the invention, the ketoxime ester compounds that may be suitably used as a photo-polymerization initiator include 3-benzoyloxyimino butan-2-one, 3-acetoxyimide butan-2-one, 3-propyonyloxyimino butan-2-one, 2-acetoxyimino pentan-3-one, 2-acetoxyimino-1-phenyl propan-1-one, 2-benzoyloxyimino-1-phenyl propan-1-one, 3-p-toluene sulfonyloxyimino butan-2-one, and 2-ethoxycarbonyloxyimino-1-phenylpropan-1-one.

(g) Borate Compounds

In the invention, the borate compounds that may be suitably used as a photo-polymerization initiator include a compound represented by the following Formula (5).

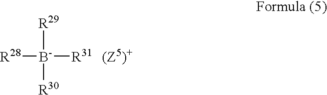

In Formula (5), R²⁸, R²⁹, R³⁰ and R³¹ each independently represent an alkyl group that may be substituted or not, an aryl group that may be substituted or not, an alkenyl group that may be substituted or not, an alkynyl group that may be substituted or not, or a heterocyclic group that may be substituted or not. Two or more of R²⁸, R²⁹, R³⁰ and R³¹ may bond together to form a ring structure, but at least one of R²⁸, R²⁹, R³⁰ and R³¹ is an alkyl group that may be substituted or not. (Z5)⁺ represents an alkali metal cation or quaternary ammonium cation.

In Formula (5), the alkyl group represented by R²⁸ to R³¹ may have a linear, branched or cyclic structure, and preferably has carbon atoms of 1 to 18. Specific examples thereof include a methyl group, an ethyl group, a propyl group, an isopropyl group, a butyl group, a pentyl group, a hexyl group, an octyl group, a stearyl group, a cyclobutyl group, a cyclopentyl group, and a cyclohexyl group. When the alkyl group has a substituent, examples thereof include a halogen atom (such as —Cl or —Br), a cyano group, a nitro group, an aryl group (preferably a phenyl group), a hydroxyl group, —COOR³² (R³² represents a hydrogen atom, an alkyl group having carbon atoms of 1 to 14 or an aryl group), —OCOR³³, —OR³⁴ (R³³ and R³⁴ each represent an alkyl group having carbon atoms of 1 to 14 or an aryl group), or a substituent represented by the following formula.

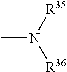

In the above formula, R³⁵ and R³⁶ each independently represent a hydrogen atom, an alkyl group having carbon atoms of 1 to 14, or an aryl group.

Specific examples of the compound represented by Formula (5) include those described in U.S. Pat. Nos. 3,567,453 and 4,343,891 and European Patent Nos. 109,772 and 109,773, and the compounds as described below.

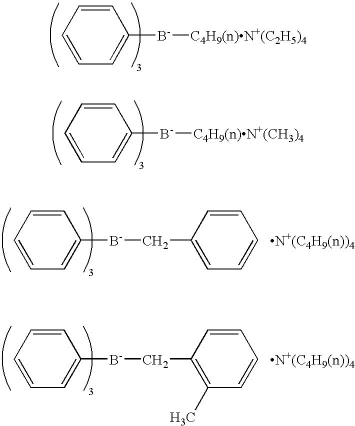

(h) Azinium Compounds

In the invention, the azinium compound that may be suitably used as a photo-polymerization initiator include those having an N-O bond described in JP-A Nos. 63-138345, 63-142345, 63-142346, 63-143537 and JP-B No. 46-42363.

(i) Active Ester Compounds

In the invention, the active ester compound that may be suitably used as a photo-polymerization initiator include the imide sulfonate compounds described in JP-B No. 62-6223 and the active sulfonate compounds described in JP-B No. 63-14340 and JP-A No. 59-174831.

(j) Carbon-Halogen Bond-Containing Compounds

In the invention, the carbon-halogen bond-containing compounds that may be suitably used as a photo-polymerization initiator include the compound represented by the following Formula (6) or Formula (7).

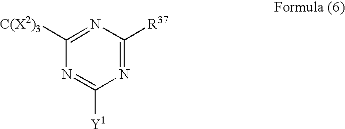

In Formula (6), X² represents a halogen atom, Y¹ represents —C(X²)₃, —NH₂, —NHR³⁸, —NR³⁸ or —OR³⁸. R³⁸ represents an alkyl group, a substituted alkyl group, an aryl group or a substituted aryl group. R³⁷ represents —C(X²)₃, an alkyl group, a substituted alkyl group, an aryl group, a substituted aryl group, or a substituted alkenyl group.

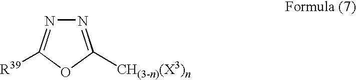

In Formula (7), R³⁹ represents an alkyl group, a substituted alkyl group, an alkenyl group, a substituted alkenyl group, an aryl group, a substituted aryl group, a halogen atom, an alkoxy group, a substituted alkoxy group, a nitro group, or a cyano group. X³ represents a halogen atom. n represents an integer of 1 to 3.

Specific examples of the compound represented by Formula (6) include the following.

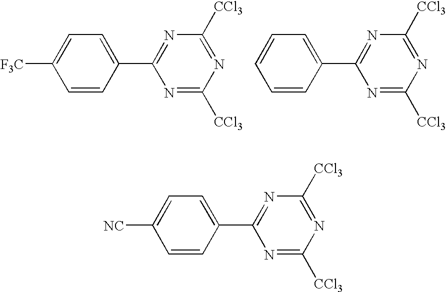

Specific examples of the compound represented by Formula (7) include the following.

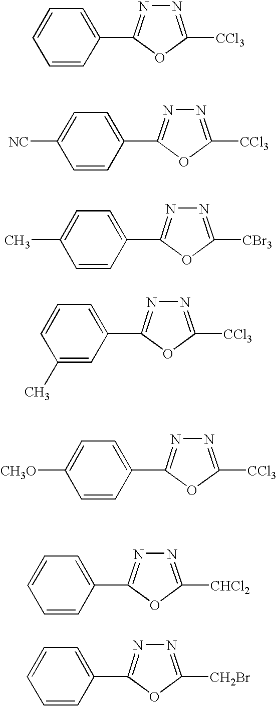

(k) Pyridium Compounds

In the invention, the pyridium compounds that may be suitably used as a photo-polymerization initiator include the compound represented by the following Formula (8).

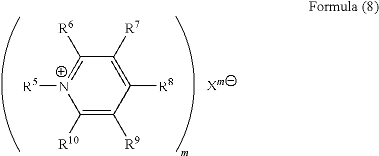

In Formula (8), R⁵ preferably represents a hydrogen atom, an alkyl group, a substituted alkyl group, an aryl group, a substituted aryl group, an alkenyl group, a substituted alkenyl group, an alkynyl group, or a substituted alkynyl group. R⁶, R⁷, R⁸, R⁹ and R¹⁰ may be the same or different from each other and represent a hydrogen atom, a halogen atom or a monovalent organic residual group, wherein at least one of R⁶, R⁷, R⁸, R⁹ and R¹⁰ has a group of a structure represented by the following Formula (9). R⁵ and R⁶, R⁵ and R¹⁰, R⁶ and R⁷, R⁷ and R⁸, R⁸ and R⁹ or R⁹ and R¹⁰ may be bound to each other to form a ring. X represents a counter anion and m represents an integer of 1 to 4.

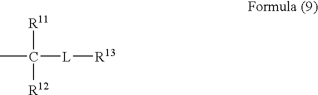

In Formula (9), R¹² and R¹³ each independently represent a hydrogen atom, a halogen atom, an alkyl group, a substituted alkyl group, an aryl group, a substituted aryl group, an alkenyl group, a substituted alkenyl group, an alkynyl group or a substituted alkynyl group. R¹¹ represents a hydrogen atom, an alkyl group, a substituted alkyl group, an aryl group, a substituted aryl group, an alkenyl group, a substituted alkenyl group, an alkynyl group, a substituted alkynyl group, a hydroxyl group, a substituted oxy group, a mercapto group, a substituted thio group, an amino group, or a substituted amino group. R¹² and R¹³, R¹¹ and R¹², or R¹¹ and R¹³ may be bound to each other to form a ring. L represents a divalent linking group including a hetero atom.

Among these photo-polymerization initiators, those having heat resistance, such as aromatic ketones, are preferred. Among these, the aromatic ketones having the following structures are more preferred.

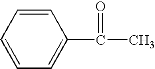

When the aromatic ketone having the above structure is linked to a polymer chain as a photo-polymerization initiation group to form a high-molecular photo-polymerization initiator, the linking group is preferably linked to the phenyl ring. Alternatively, the phenyl ring may be directly linked to the polymer chain.

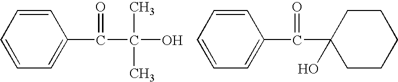

When the above aromatic ketones are linked to a polymer chain as a photo-polymerization initiation group to form a high-molecular photo-polymerization initiator, the linking group is preferably linked to the phenyl ring or the OH. Alternatively, the phenyl ring or the OH may be directly linked to the polymer chain.

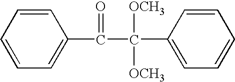

When the above aromatic ketone is linked to a polymer chain as a photo-polymerization initiation group to form a high-molecular photo-polymerization initiator, the linking group is preferably linked to the phenyl ring. Alternatively, the phenyl ring may be directly linked to the polymer chain.

Examples of the linking group at which the aromatic ketone is linked to the polymer chain include a divalent or trivalent linking group, such as —O—, —OCO—, —CO—, —OCONH—, —S—, —CONH—, —OCOO—, —N═, or a combination thereof. Among these, —O— or —OCO— is preferably used.

The photopolymerization initiator used in the invention may be a low-molecular initiator or a high-molecular initiator such as those mentioned above.

In view of improving adhesiveness of the adhesion layer to the adjacent substrate or metal layer, a high-molecular photo-polymerization initiator is preferably used. The weight average molecular weight of the high-molecular photo-polymerization initiator is preferably 10,000 or more, more preferably from 30,000 to 100,000.

Other than the aforementioned high-molecular photo-polymerization initiators, for example, a high-molecular compound having an active carbonyl group in a side chain, such as those described in JP-A Nos. 9-77891 and 10-45927 may also be used.

More specifically, the high-molecular photo-polymerization initiators include compounds having the following structures (a) to (n).

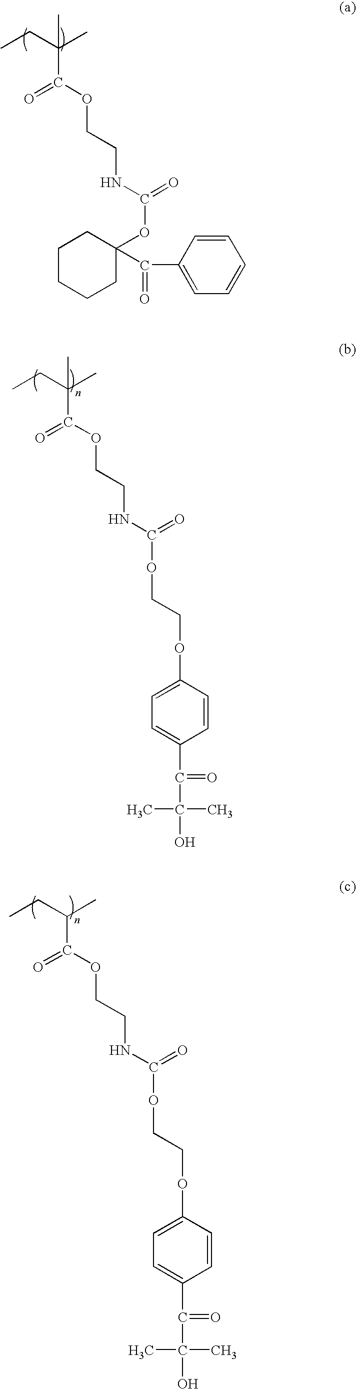

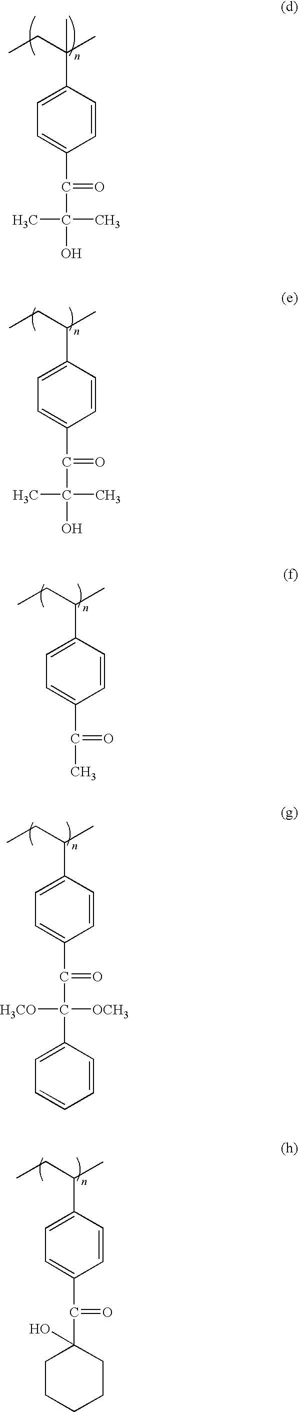

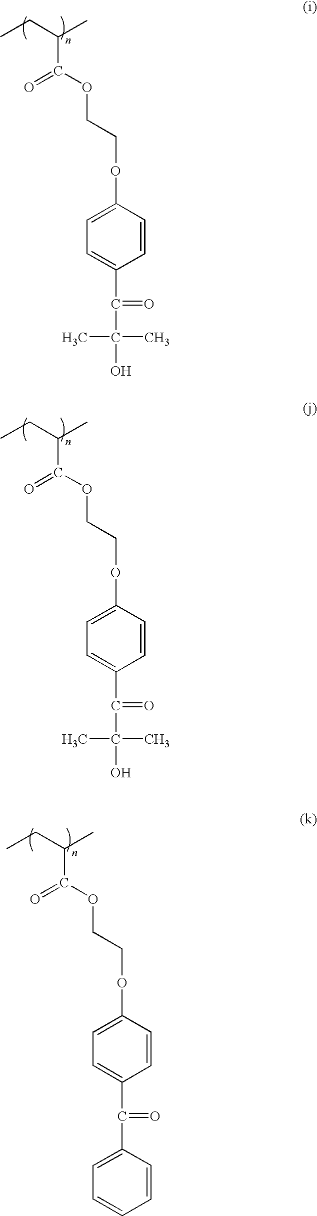

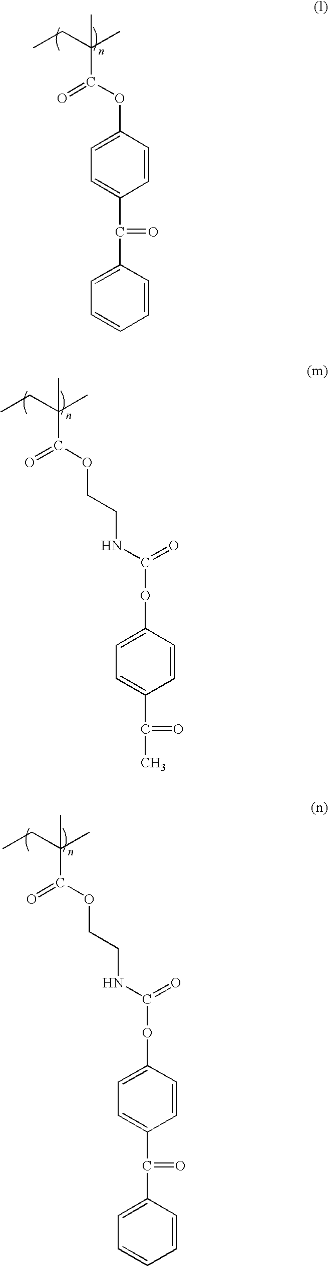

Further, the high-molecular photo-polymerization initiator may be a copolymer including a repeating unit derived from a monomer having a photo-polymerization initiating group and a repeating unit derived from a monomer of other kind, such as the one having the following structure.

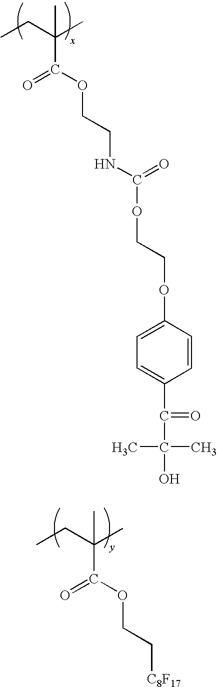

The composition for forming an adhesive layer in the invention may include an epoxy resin capable of initiating photo-polymerization. The epoxy resin capable of initiating photo-polymerization may be easily obtained by, for example, copolymerizing a monomer having an epoxy group and a monomer having a photo-polymerization initiating group.

The following are specific examples of epoxy resin capable of initiating photo-polymerization that is obtained by copolymerizing a monomer having an epoxy group and a monomer having a photo-polymerization initiating group. However, the epoxy resin that may be used in the invention is not limited thereto.

In the following copolymers (C) to (N), x and y represent a molar fraction, where x+y=100 (neither x nor y is 0).

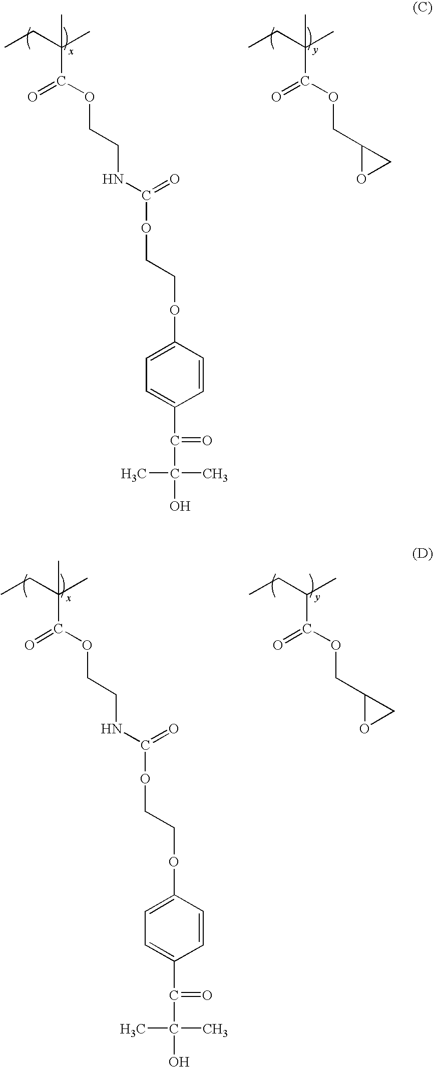

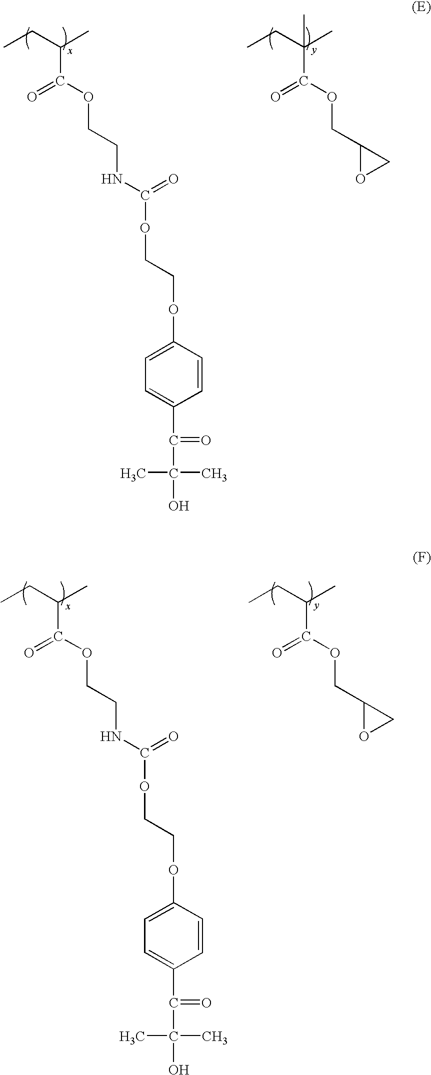

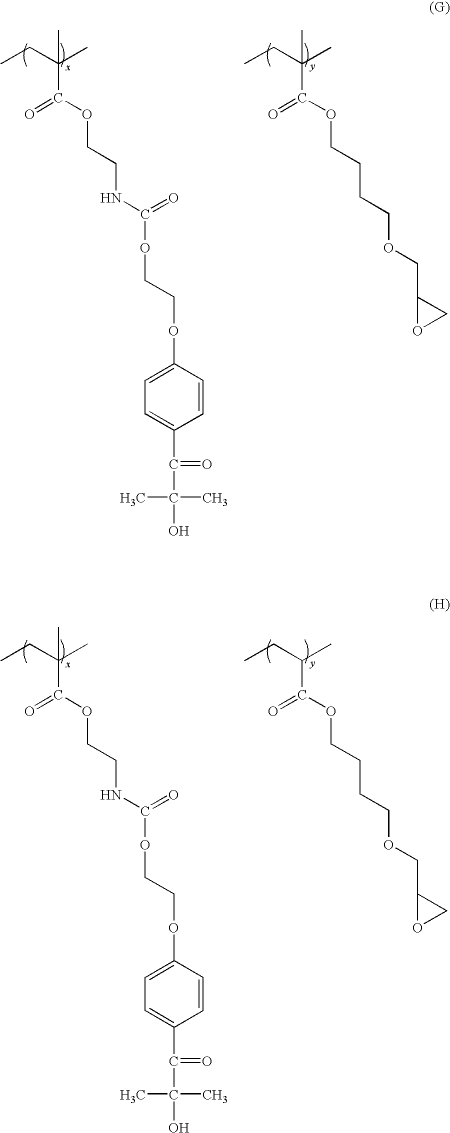

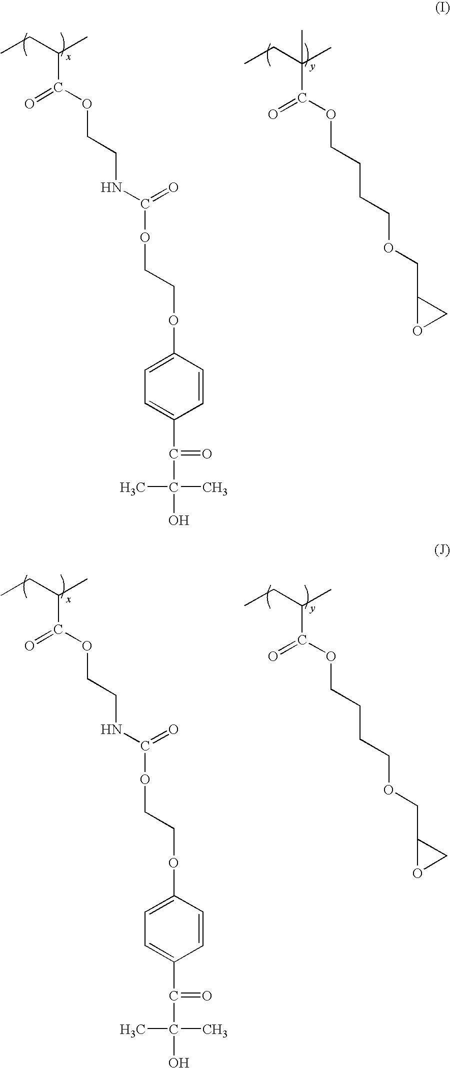

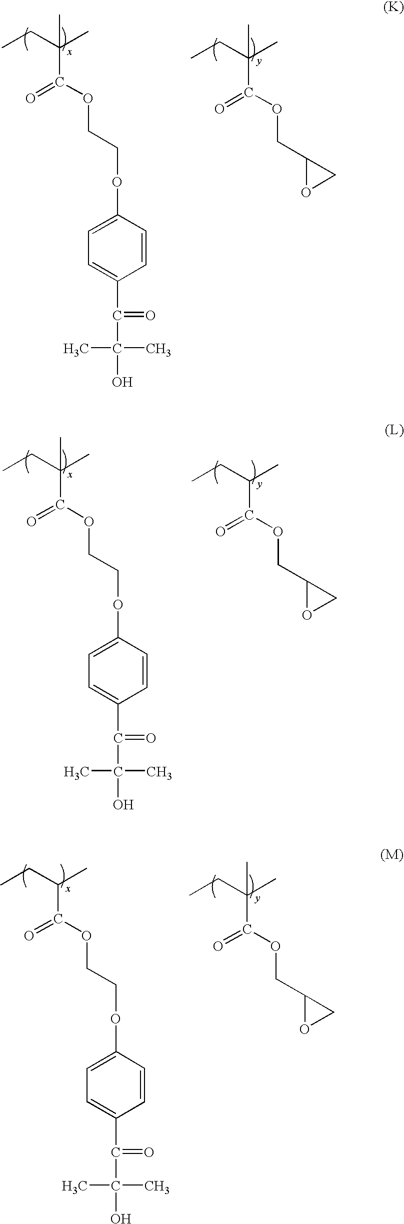

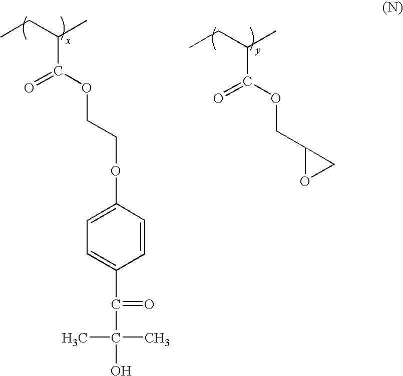

Among the above copolymers, the molar fraction represented by x and y preferably satisfies that x is 5 to 70 and y is 30 to 95, more preferably x is 5 to 50 and y is 50 to 95, and particularly preferably 10 to 30 and y is 70 to 90, from the viewpoint of film strength or graft polymerizability.

The polymerization initiator that may be used in the invention is not limited to the aforementioned polymerization initiators, but may be appropriately selected from known polymerization initiators.

The polymerization initiator may be used alone or in combination of two or more kinds.

When the composition for forming an adhesive layer that may used in the invention contains a polymerization initiator, the amount thereof is typically 0.1% by mass to 50% by mass, preferably 1% by mass to 30% by mass, with respect to the total solid content of the composition. When the content is within the above range, reduction in sensitivity or strength of the adhesive layer can be effectively suppressed. —Sensitizer—

The composition for forming an adhesive layer in the invention may include a sensitizer in order to enhance the sensitivity, in addition to the above-mentioned photo-polymerization initiator.

Examples of the sensitizers include n-butylamine, triethylamine, tri-n-butyl phosphine, and thioxanthone derivatives. —Solvent—

The composition for forming an adhesive in the invention may include a solvent.

Examples of the organic solvent include aromatic hydrocarbons such as toluene and xylene, acetates such as ethyl acetate, butyl acetate and propylene glycol monomethyl ether acetate, glycol ethers such as ethylene glycol monomethyl ether and ethylene glycol monoethyl ether, glycol derivatives such as methyl cellosolve acetate and ethyl cellosolve acetate, ketones such as acetone, methyl ethyl ketone and cyclohexanone, ethers such as tetrahydrofuran, dimethyl formamide, dimethyl acetoamide, N-methyl pyrolidone, dimethyl sulfoxide, sulfolane and 1-methoxy-2-propanol.

The organic solvent may be used alone or in combination of two or more kinds. —Formation of Adhesive Layer—

The adhesive layer may be formed by a method including uniformly applying the above-mentioned composition for forming an adhesive layer onto the above-mentioned substrate by knife coating, roll coating, curtain coating, spin coating, bar coating, dip coating or the like, and then drying the same.

The heating temperature for drying is preferably 20° C. to 90° C., more preferably 50° C. to 80° C. The heating time is from 1 second to 50 hours, more preferably from 100 seconds to 3 hours.

After the completion of applying and drying the composition for forming an adhesive layer, energy is applied thereto. The application of energy may be conducted by heating or exposing to light such as actinic rays. The heating may be conducted by heating a multilayer structure of the substrate and the film formed from the composition by using a contact type or non-contact type heating source, conveying the multilayer structure through a heated zone, or placing the multilayer structure in a heated zone.

For example, the contact heating may be conducted by contacting the multilayer structure to a heat roller including a heater, and the non-contact heating may be conducted by heating the multilayer structure with an infrared heater, blowing the same with a hot air, or placing the same in a high-temperature atmosphere.

The heating is preferably conducted at 50° C. to 90° C. for 5 to 60 minutes.

When the energy is applied by light exposure with actinic rays or the like, the exposure can be conducted using a common light source such as a mercury lamp, a metal halide lamp, a xenon lamp, a chemical lamp, a carbon arc lamp, a light emitting diode (LED), a semiconductor laser, or a fluorescent lamp. It is also possible to use a hot-cathode tube, a cold-cathode tube, light source of electron beams, X-rays or the like, electromagnetic waves, or the like.

In the invention, a mercury lamp, an LED, or a semiconductor laser is preferably used as the light source. The LED and semiconductor laser are characterized by their small size. In particular, the LED has a long operating life, generates less heat, consumes less electricity, generates no ozone, and is capable of being immediately used upon application of power.

Further, a pattern can be formed by performing light beam scanning exposure, or performing pattern exposure using a mask.

After the completion of energy application, the adhesive layer is preferably washed with a solvent such as water in order to remove the unreacted compound remaining in the adhesive layer.

The thickness of the adhesive layer in the invention is preferably 0. 1 m to 10 μm, more preferably 0.2 μm to 5 m, from the viewpoint of adhesion strength.

Step (a2)

In step (a2) of the method of producing a multilayer structure <2>, an adhesive layer is formed on a metal foil by applying the composition containing an acrylic resin including a repeating unit derived from an ethylenic unsaturated monomer having a divalent sulfur atom, and then applying energy to the composition. In other words, step (a2) is different from step (a1) in that the adhesive layer is formed on the metal foil, rather than on the substrate.

In the following, the metal foil used in this step is described.

<Metal Foil>

Examples of the metal foil that may be used in the invention include a copper foil, a tin foil, a lead foil, a tin-lead alloy foil, a nickel foil, a silver foil or an indium foil. Among these, a copper foil is preferred.

The thickness of the metal foil is preferably 5 to 400 μm, more preferably 9 to 120 μm.

<Adhesive Layer>

In step (a2), the adhesive layer is formed on the above-mentioned metal foil.

The method of preparing the composition used in step (a2) for forming an adhesive layer, and forming an adhesive layer from the composition, may be the same as those used in step (a1), and preferable embodiments are also the same.

The adhesive layer is formed on the substrate in the previous step (a1), while the adhesive layer is formed on the metal foil in step (a2).

Step (b1)

In step (b1), a metal layer is formed on the adhesive layer that has been formed on the substrate in step (a1) by a process of: (1) laminating a metal foil, or (2) performing evaporation or sputtering. In the following, the processes (1) and (2) are described.

<(1) Process of Laminating a Metal Foil>

A metal layer may be formed by laminating a metal foil to the adhesive layer that has been formed on the substrate in step (a1).

Examples of the method of laminating a metal foil to the adhesive layer formed on the substrate include a method described in paragraphs [0016] to [0028] of JP-A No. 2002-204047.

The metal foil (such as a copper foil) is preferably laminated to the adhesive layer formed on the substrate while applying heat and pressure at a temperature of 40° C. to 140° C., more preferably 50° C. to 80° C. When the temperature is within the above range, the adhesive layer becomes adhesive and favorably adheres to the metal foil, while suppressing the displacement of metal foil and adhesive layer due to the difference in thermal expansion characteristics. The pressure to be applied during the lamination is preferably 0. 1 MPa to 20 MPa, more preferably 0.4 MPa to 10 MPa.

Examples of the metal foil used in the invention include a copper foil, a tin foil, a lead foil, a tin-lead alloy foil, a nickel foil, a silver foil and an indium foil. Among these, a copper foil is most preferred. The thickness of the metal oil is 5 μm to 400 μm, more preferably 9 μm to 120 μm.

<(2) Process of Forming a Metal Layer by Evaporation or Sputtering>

A metal layer may be formed on the adhesive layer that has been formed on the substrate in step (a1) by performing evaporation or sputtering.

Examples of the method of forming a metal layer on an adhesive layer by evaporation or sputtering include a method described in paragraphs [0017] to [0030] of JP-A No. 2008-91596.

The metal film (metal layer) formed by evaporation or sputtering is preferably at least one selected from the group consisting of a nickel layer, a chromium layer, a copper layer and an alloy layer including at least two of nickel, chromium and copper. Among these, a copper layer is preferred in view of environmental suitability.

The thickness of the metal film (metal layer) is not particularly limited, and a copper layer as a conductive layer may be formed on the metal film (metal layer) to a desired thickness.

In the invention, electroless plating and/or electroplating may be performed using the metal layer formed by evaporation or sputtering as a plating nucleus.

In this case, the electroless plating and electroplating may be performed by the following methods.

(Electroless Plating)

The electroless plating is a process of precipitating a metal by chemical reaction using a solution containing ions of a metal to be precipitated as a plating film.

In the invention, the electroless plating may be performed by, for example, immersing a substrate on which a metal film is formed by evaporation or sputtering in an electroless plating bath. Known electroless plating baths may be used as the electroless plating bath.

The electroless plating bath typically includes ions of a metal used for plating, a reduction agent, and an additive that improves stability of the metal ion (stabilizer), as major components. The electroless plating bath may further include other known additives such as a stabilizer for the elecroplating plating bath.

Examples of the metal to be used in the electroless plating bath include copper, tin, lead, nickel, gold, palladium and rhodium. Among these, copper and gold are particularly preferred in view of conductivity.

There are reduction agents or additives that are suitable for each kind of the metal. For example, a copper electroless plating bath contains Cu(SO₄)₂ as a copper salt, HCOH as a reduction agent, and a chelating agent such as EDTA or Rochelle salt as a stabilizer for copper ion. A CoNiP electroless plating bath contains cobalt sulfate and nickel sulfate as a metal salt, sodium hypophosphite as a reduction agent, and sodium malonate, sodium maleate, and sodium succinate as a complexing agent. A palladium electroless plating bath contains (Pd(NH₃)₄)Cl₂ as a metal ion, NH₃ and H₂NNH₂ as a reduction agent, and EDTA as a stabilizer. The electroless plating bath may contain other components than the above.

The thickness of the metal layer may be regulated by controlling the concentration of the metal ion in the electroless plating bath, the immersion time in the electroless plating bath, or the temperature of the electroless plating bath. In view of achieving conductivity, the thickness is preferably 0.5 μm or more, more preferably 3 μm or more.

The time for immersion in the electroless plating bath is preferably from 1 minute to about 3 hours, more preferably from 1 minute to about 1 hour.

(Electroplating)

The electroplating is performed by using the metal film formed by evaporation or sputtering as an electrode.

In the invention, the electroplating may be performed by known methods. Examples of the metal that may be used for electroplating in the invention include copper, chromium, lead, nickel, gold, silver, tin and zinc. Among these, copper, gold and silver are preferred in view of conductivity, and copper is most preferred.

The thickness of the metal layer formed by electroplating may differ depending on applications, and may be regulated by controlling the concentration of metal ion in the plating bath, immersion time, or current density. For typical applications such as electric wiring, the thickness of the metal layer is preferably 0.3 μm or more, more preferably 3 μm or more, in view of conductivity.

Step (b2)

In step (b2), a substrate is formed by (3) forming a layer of organic resin by a casting method on the adhesive layer that has been formed on the metal foil in the above-mentioned step (a2). In the following, the process (3) is described.

<(3) Forming an Organic Resin Layer by a Casting Method>

When an adhesive layer is formed on a metal foil in step (a2), a substrate may be formed by forming an organic resin layer on the adhesive layer by a casting method.

Examples of the method of forming an organic resin layer on the adhesive layer with a metal foil include a method described in paragraphs [0011 ] to [0044] of JP-A No. 2000-133892.

The organic resin layer may be formed by, for example, forming a film of polyimide varnish such as polyamic acid varnish by a casting method and then imidizing the same at high temperature to form a polyimide layer.

As mentioned above, the substrate and the metal layer can be tightly adhered to each other by the adhesive layer provided in between, by conducting steps (a1) and (b1) in the method of producing a multilayer structure of the invention <1>, or by conducting steps (a2) and (b2) in the method of producing a multilayer structure of the invention <2>. Therefore, even when the substrate has a highly smooth surface, adhesiveness between the substrate and the metal layer that is high enough for practical applications can be obtained.

Applications for Printed Circuit Boards

The metal layer of a multilayer structure produced by the method of the invention may be used for wiring of a printed circuit board by performing patterning by a known method. The wiring of a printed circuit board formed from the metal layer according to the invention also has such an advantage of excellent adhesiveness to a substrate having a smooth surface.

In the following, methods of patterning for forming wiring of a printed circuit board are described.

(Etching Process)

In this process, a metal layer of the multilayer structure formed in the above-mentioned method is etched in a patterned manner. The etching may be performed by any methods, and typical examples thereof include a subtractive method and a semi-additive method.

The subtractive method is a method of forming a metal pattern, and the method includes providing a dry film resist layer on a metal layer of a multilayer structure; forming a dry film resist pattern that corresponds to a metal pattern to be formed by exposing the dry film resist film to light in a patterned manner, and then developing the same; and removing the metal layer by an etching solution using the dry film resist pattern as a mask. The dry film resist may be formed from any materials, such as those of negative type, positive type, liquid type or film type. The etching may be performed by any process used in the production of printed circuit boards, such as wet etching or dry etching. In view of operation suitability, a wet etching apparatus or the like is simple and preferable. Examples of the etching solution include an aqueous solution of copper chloride or ferric chloride.

The semi-additive method is a method of forming a metal pattern, and the method includes providing a dry film resist layer on a metal layer of a multilayer structure; forming a dry film resist pattern that corresponds to a portion other than a metal pattern to be formed by exposing the dry film resist layer to light in a patterned manner, and then developing the same; performing electroplating using the dry film resist pattern as a mask; removing the dry film resist pattern; and performing quick etching to remove a portion of the metal layer in a patterned manner. The same dry film resist and etching solution that may be used in the subtractive method may also be used in the semi-additive method. Further, the electroplating may be performed by the method as mentioned above.

A printed circuit board may be obtained through the above-mentioned process. The obtained printed circuit board has a metal pattern (wiring) that exhibits excellent adhesiveness to the substrate. Moreover, the printed circuit board exhibits excellent insulation reliability between each portion of the metal pattern.

In particular, as mentioned later, the amount of electric loss at high-frequency transmission may be reduced by using a smooth substrate having less surface roughness for the printed circuit board.

The printed circuit board obtained according to the invention includes a plating film that is formed on an organic resin substrate having a surface roughness (Rz) of 500 nm or less (more preferably 100 nm or less) via an adhesive layer. As mentioned above, the printed circuit board obtained according to the invention exhibits excellent adhesiveness between the plating film and the substrate, and the adhesiveness is preferably 0.6 kN/m or more.

The surface roughness of the substrate may be measured by cutting the substrate in a perpendicular direction to its surface and observing the cross-section by an SEM.

The multilayer structure produced by the method of the invention includes an organic resin layer. Further, a multilayer printed circuit board may be produced by a build-up method with an electric circuit substrate formed on a substrate including an organic resin layer or an insulating layer.

The following are exemplary embodiment of the invention. However, the invention is not limited thereto.
<1> A method of producing a multilayer structure including a substrate, an adhesive layer and a metal layer, the method comprising:

(a1) forming the adhesive layer on the substrate by applying a composition to the substrate, the composition comprising an acrylic resin having a repeating unit that is derived from an ethylenic unsaturated monomer having a divalent sulfur atom, and applying energy to the composition; and

(b1) forming the metal layer on the adhesive layer by laminating a metal foil or by forming a metal film by evaporation or sputtering.
<2> The method according to <1>, further comprising performing electroless plating or electroplating using the metal layer as a plating nucleus.
<3> The method according to <1>, wherein the composition further comprises a compound that cures upon application of heat or light.
<4> The method according to <1>, wherein the acrylic resin includes a component that cures upon application of heat or light.
<5> The method according to <1>, wherein the composition further comprises a photo-polymerization initiator.
<6> The method according to <1>, wherein the substrate comprises a metal, an organic resin, or a multilayer structure including an organic resin and a metal.
<7> The method according to <6>, wherein the metal layer comprises silver, copper or gold.
<8> The method according to <7>, wherein the metal layer comprises copper.
<9> The method according to <1>, wherein the metal layer is formed in a patterned manner.
<10> The method according to <6>, wherein the organic resin comprises a resin selected from the group consisting of epoxy resin, polyimide resin, polyester resin, polycarbonate resin, and ABS resin.
<11> A method of producing a multilayer structure including a substrate, an adhesive layer and a metal layer, the method comprising:

(a2) forming the adhesive layer on a metal foil that forms the metal layer by applying a composition to the metal foil, the composition comprising an acrylic resin having a repeating unit that is derived from an ethylenic unsaturated monomer having a divalent sulfur atom, and applying energy to the composition; and

(b2) forming the substrate on the adhesive layer by forming a film of an organic resin by a casting method.
<12> The method according to <11>, wherein the composition further comprises a compound that cures upon application of heat or light.
<13> The method according to <11>, wherein the acrylic resin includes a component that cures upon application of heat or light.
<14> The method according to <11>, wherein the composition further comprises a photo-polymerization initiator.
<15> The method according to <11>, wherein the metal foil is selected from the group consisting of a copper foil, a tin foil, a lead foil, a tin-lead alloy foil, a nickel foil, a silver foil or an indium foil.
<16> The method according to <15>, wherein the metal foil is a copper foil.
<17> The method according to <11>, wherein the metal layer is formed in a patterned manner.
<18> The method according to <11>, wherein the organic resin comprises a resin selected from the group consisting of epoxy resin, polyimide resin, polyester resin, polycarbonate resin, and ABS resin.

### EXAMPLES

In the following, the invention will be explained in detail with reference to the Examples and the Comparative Examples. However, the invention is not limited thereto.

### Example 1

### Synthesis Example 1

### Preparation of Acrylic Resin A

24 parts by mass of N,N-dimethylacetoamide were heated to 80° C. Then, a mixture of 2.69 parts by mass of ethylthioethylmethacrylate and 10.0 parts by mass of acrylic acid (monomer composition) and a mixture of 0.355 parts by mass of dimethyl 2,2′-azobis (isobutylate) (trade name: V-601, manufactured by Wako Pure Chemical Industries, Ltd.) and 12 parts by mass of N,N-dimethylacetoamide (initiator composition) were dropped at the same time into the N,N-dimethylacetoamide over 1.5 hours, respectively, under a nitrogen stream. After the dropping, the mixture was further heated to 80° C. for 5.5 hours under a nitrogen stream. Subsequently, a mixture of 4.22 parts by mass of monomer A (having the following structure), 0.038 parts by mass of 2,2,6,6-tetramethyl-1-piperidinyloxy, radical (TEMPO), 0.70 parts by mass of benzyltriethyl ammonium chloride and 12 parts by mass of N,N-dimethylacetoamide was added and the resultant was heated to 90° C. for 4 hours. Thereafter, the reaction solution was cooled to room temperature and was dropped into ethyl acetate for re-precipitation. The solid that had precipitated was filtered and dried, and acrylic resin A was obtained (weight average molecular weight: 73,000, acid value: 296 mgKOH/g).

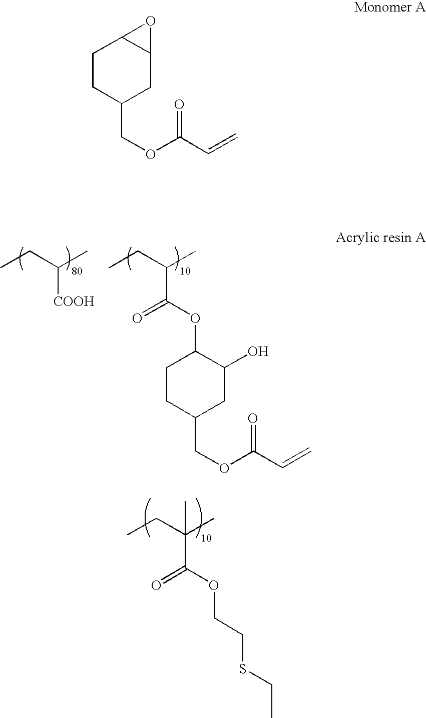

Formation of Acrylic Resin Composition Layer

A polyimide film (trade name: KAPTON 500H, manufactured by DuPont-Toray Co., Ltd., thickness: 128 μm) was used as the substrate. An acrylic resin composition layer having a thickness of 1 μm was formed by applying the following composition for adhesive layer A on the substrate with a spin coater, and then drying the same at 60° C. for 5 minutes.

Composition for Adhesive Layer A

| | |
|---|---|
| (A) Acrylic resin A | 10 parts by mass |
| (B) 1-methoxy-2-propanol (manufactured by Wako | 124 parts by mass |
| Pure Chemical Industries, Ltd.) | |

Formation of Adhesive Layer by Applying Energy

The application of energy was performed by irradiating the entire surface of acrylic resin composition layer side of the multilayer structure obtained in the above process with a 1500 W high-pressure mercury lamp (trade name: UVX-02516S1LP01, manufactured by Ushio, Inc., light intensity at 254 nm: 38 mW/cm²). After the light irradiation, the multilayer structure was immersed in an aqueous solution containing 1 mass % of sodium hydrogen carbonate (manufactured by Wako Pure Chemical Industries, Ltd.) at 25° C. for 5 minutes to remove the resin that was not sufficiently cured.

Formation of Metal Layer

Multilayer structure A having a metal layer formed from a copper foil was obtained by laminating a rolled copper foil having a thickness of 18 μm (manufactured by Nippon Foil Mfg. Co., Ltd.) to the adhesive layer obtained in the above process with a pressure of 0.2 MPa at 80° C.

Evaluation of Peel Strength

The peel strength of the metal layer of multilayer structure A was measured with a testing apparatus (trade name: TENSILON, type: RTM-100, manufactured by Orientec Co., Ltd.) in accordance with JIS C 6481, and the average of maximum value and minimum value was determined as the peel strength of the metal layer. The results are shown in the following Table 2.

### Example 2

Multilayer structure B was obtained in a similar manner as Example 1, except that composition A′ containing the same amount of acrylic resin B having the following structure (weight average molecular weight: 68,000) instead of acrylic resin A was used.

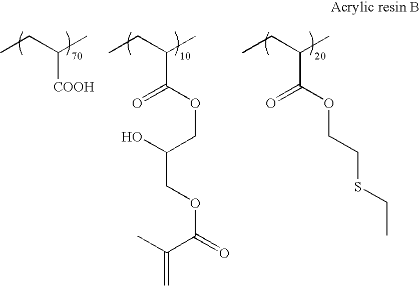

### Example 3

Multilayer structure C was obtained in a similar manner as Example 1, except that composition A″ containing the same amount of acrylic resin C having the following structure (weight average molecular weight: 58,000) instead of acrylic resin A was used.

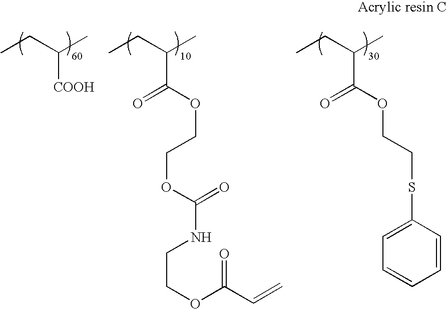

### Example 4

### Synthesis Example 2

### Preparation of Low Temperature-Curable Latent Curing Agent

Compound (I-1) having the following structure was obtained by reacting 1.0 mol of nonyl phenol with 2.0 mol of formalin and 2.0 mol of 2-methyl imidazole, at 180° C. for 3 hours.

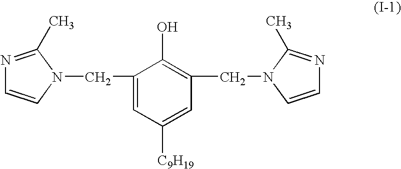

The average molecular weight (Mw) of compound (I-1) as measured by a GPC (gel permeation chromatography) system (trade name: SHODEX GPC R1-71, manufactured by Showa Denko K.K.) was 402. This value almost coincided with the theoretical molecular weight of the reactant.

1 mol of compound (I-1) was dissolved in 363 ml of a xylene/DMF solution (2:1). The concentration of compound (I-1) in the resultant solution was 50 mass %. Thereafter, 0.6 mol of a liquid-type epoxy resin (1-2) (trade name: EPIKOTE 828, bisphenol A epoxy resin, weight average molecular weight: 380) was added to the solution, and was allowed to react with compound (I-1) at 70° C. Then, the xylene-DMF solution was distilled away under reduced pressure to obtain a low temperature-curable latent curing agent containing an epoxy resin adduct (I). The molar ratio of compound (I-1):epoxy resin (I-2) at this time was 1:0.6.

This low temperature-curable latent curing agent is useful for curing an epoxy resin at low temperature.

A polyimide film (trade name: KAPTON 500H, manufactured by Du Pont-Toray Co., Ltd., thickness: 128 μm) was used as the organic resin substrate. An epoxy resin layer having a thickness of 5 μm was formed by applying the following epoxy resin composition A on the substrate using a coating bar, and then drying the same at 70° C. for 2 hours.

Epoxy Resin Composition A

| | |
|---|---|
| (A) Epoxy resin (trade name, EPIKOTE 828, | 10 parts by mass |
| manufactured by Japan Epoxy Resins Co., Ltd.) | |
| (B) Low temperature-curable latent curing | 2 parts by mass |
| agent (compound obtained in Synthesis Example 2) | |

The subsequent steps of forming an acrylic resin composition layer, forming an adhesive layer from the acrylic resin composition layer, and forming a metal layer were performed in a similar manner to Example 1, and multilayer structure D was thus obtained.

### Example 5

Multilayer structure E was obtained in a similar manner to Example 4, except that the following epoxy resin composition B was used instead of epoxy resin composition A used in Example 4.

Epoxy Resin Composition B

| | | |
|---|---|---|
| (A) Epoxy resin (trade name, EPIKOTE 828, | 10 | parts by mass |
| manufactured by Japan Epoxy Resins | | |
| Co., Ltd.) | | |
| (B) Low temperature-curable latent curing | 2 | parts by mass |
| agent (compound obtained in Synthesis | | |
| Example 2) | | |
| (C) Photo-polymerization initiator | 1.3 | parts by mass |
| (trade name: IRGACURE 2959, manufactured by | | |
| Ciba Japan, K.K.) | | |

IRGACURE 2959

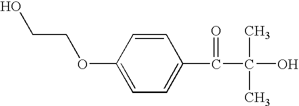

### Example 6

Formation of Acrylic Resin Composition Layer

An acrylic resin composition layer having a thickness of 1 μm was formed by applying the following composition for adhesive layer A to an electrolytic copper foil having a thickness of 18 μm (manufactured by Mitsui Mining & Smelting Co., Ltd.) using a spin coater, and then drying the same at 60° C. for 5 minutes.

Composition for Adhesive Layer A

| | |
|---|---|
| (A) Acrylic resin A | 10 parts by mass |
| (B) 1-methoxy-2-propanol (manufactured by Wako | 124 parts by mass |
| Pure Chemical Industries, Ltd.) | |

Formation of Adhesive Layer by Applying Energy

The application of energy was performed by irradiating the entire surface of acrylic resin composition layer side of the multilayer structure obtained in the above process with a 1500 W high-pressure mercury lamp (trade name: UVX-02516S1LP01, manufactured by Ushio, Inc., light intensity at 254 nm: 38 mW/cm²). After the light irradiation, the multilayer structure was immersed in an aqueous solution containing 1 mass % of sodium hydrogen carbonate (manufactured by Wako Pure Chemical Industries, Ltd.) at 25° C. for 5 minutes to remove the resin that was not sufficiently cured.

Formation of Organic Resin Layer

A polyamic acid film (polyimide precursor film) having a thickness of 30 μm was formed by applying a N-methyl-2-pyrolidone (NMP) solution containing 12 mass % of polyamic acid to the adhesive layer, and then drying the same at 140° C. Subsequently, pre-heating was performed to remove the NMP at 160° C., 200° C. and 230° C., respectively. Thereafter, the polyamic acid film was imidized by heating in a nitrogen atmosphere oven at 350° C. for 1 hour, thereby obtaining a polyimide film. Multilayer structure F was thus obtained.

### Example 7

Multilayer structure G was obtained in a similar manner to Example 6, except that the following composition for adhesive layer B was used instead of composition for adhesive layer A.

Composition for Adhesive Layer B

| | |
|---|---|
| (A) Acrylic resin A | 10 parts by mass |
| (B) 1-methoxy-2-propanol (manufactured by Wako | 124 parts by mass |
| Pure Chemical Industries, Ltd.) | |
| (C) Photo-polymerization initiator (trade name: | 0.2 parts by mass |
| IRGACURE 2959, manufactured by Ciba Japan, | |
| K.K.) | |

### Example 8

Formation of Adhesive Layer

An adhesive layer was formed from composition for adhesive layer B in a similar manner to Example 7, on a substrate of a glass epoxy resin (manufactured by Panasonic Corporation).

Formation of Metal Layer

A rolled copper foil having a thickness of 18 μm (manufactured by Nippon Foil Mfg. Co., Ltd.) was laminated to the adhesive layer obtained in the above process with a pressure of 0.2 MPa at 80° C. Multilayer structure H having a metal layer formed from a copper foil was thus obtained.

### Example 9

Formation of Adhesive Layer

An adhesive layer was formed from composition for adhesive layer B in a similar manner to Example 7, on a substrate of a PET film (trade name: TOYOBO ESTER FILM, product name: A4100, product number: 145102071-3, thickness: 188 μm, manufactured by Toyobo., Ltd.)

Formation of Metal Layer

A rolled copper foil having a thickness of 18 μm (manufactured by Nippon Foil Mfg. Co., Ltd.) was laminated to the adhesive layer obtained in the above process with a pressure of 0.2 MPa at 80° C. Multilayer structure I having a metal layer formed from a copper foil was thus obtained.

### Example 10

Formation of Adhesive Layer

An adhesive layer was formed on a substrate of a polyethylene naphthalate (PEN) film (trade name: TEONEX Q65FA, manufactured by Teijin DuPont Films Japan Ltd.) using composition for adhesive layer B, in a similar manner to Example 7.

Formation of Metal Layer

Multilayer structure J having a metal layer of a copper foil was obtained by forming a copper film having a thickness of 100 nm by sputtering using a sheet-feed vacuum sputtering evaporation bath (manufactured by ULVAC, Inc.).

### Example 11

Formation of Adhesive Layer

An adhesive layer was formed on a substrate of a polycarbonate resin (manufactured by Takiron Co., Ltd.) using composition for adhesive layer B, in a similar manner to Example 7.

Formation of Metal Layer

Multilayer structure K having a metal layer of a copper foil was obtained by forming a copper film having a thickness of 100 nm by sputtering using a sheet-feed vacuum sputtering evaporation bath (manufactured by ULVAC, Inc.).

### Example 12

Formation of Adhesive Layer

An adhesive layer was formed on a substrate of an ABS resin (manufactured by Kanki Kako-zai limited.) from composition for adhesive layer B, in a similar manner to Example 7.

Formation of Metal Layer

Multilayer structure L having a metal layer of a copper foil was obtained by forming a copper film having a thickness of 100 nm by sputtering using a sheet-feed vacuum sputtering evaporation bath (manufactured by ULVAC, Inc.).

### Comparative Example 1

Multilayer structure CA was obtained in a similar manner to Example 1, except that the following acrylic resin D (weight average molecular weight: 74,000) was used instead of acrylic resin A.

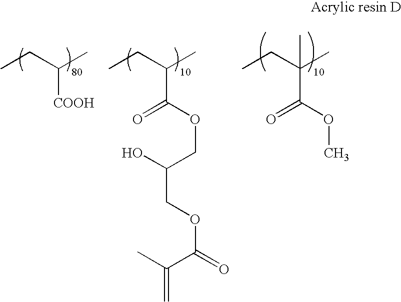

### Comparative Example 2

Multilayer structure CB was obtained in a similar manner to Example 1, except that the following acrylic resin E (weight average molecular weight: 60,000) was used instead of acrylic resin A.

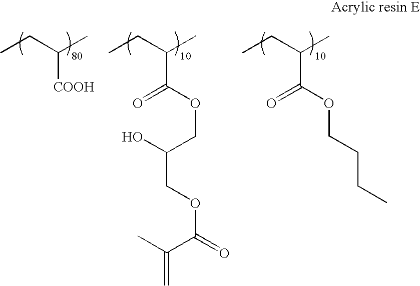

### Example 13

Preparation of Substrate

A polyimide film (trade name: KAPTON 500H, manufactured by DuPont-Toray Co., Ltd., thickness: 128 μm) was used as the organic resin substrate. An epoxy resin layer having a thickness of 5 μm was formed by applying the following epoxy resin composition C on the substrate with a coating bar, and then drying the same at 70° C. for 2 hours.

Epoxy Resin Composition C

| | |
|---|---|
| (A) Epoxy resin (trade name, EPIKOTE 828, | 10 parts by mass |
| manufactured by Japan Epoxy Resins Co., Ltd.) | |
| (B) Low temperature-curable latent curing agent | 2 parts by mass |
| (compound obtained in Synthesis Example 2) | |
| (C) Trimethylol propane trimethacrylate (manufactured | 3 parts by mass |
| by Wako Pure Chemical Industries, Ltd.) | |

Formation of Adhesive Layer

An adhesive layer was formed on a substrate obtained in the above process from composition for adhesive layer B, in a similar manner to Example 7.

Formation of Metal Layer

Multilayer structure M having a metal layer formed from a copper foil was obtained by laminating a rolled copper foil having a thickness of 18 μm (manufactured by Nippon Foil Mfg. Co., Ltd.) to the adhesive layer obtained in the above process with a pressure of 0.2 MPa at 80° C.

### Example 14

An adhesive layer containing acrylic resin C was formed on an electrolytic copper foil having a thickness of 18 μm (manufactured by Mitsui Mining & Smelting Co., Ltd.) in a similar manner to Example 3. Then, a polyamic acid film (polyimide precursor film) having a thickness of 30 μm was formed on the adhesive layer by applying a N-methyl-2-pyrolidone (NMP) solution containing 12 mass % of polyamic acid, and then drying the same at 140° C. Subsequently, pre-heating was performed to remove the NMP at 160° C., 200° C. and 230° C., respectively. Thereafter, the polyamic acid film was imidized by heating in a nitrogen atmosphere oven at 350° C. for 1 hour, thereby obtaining a polyimide film. Multilayer structure N was thus obtained.

### Example 15

Preparation of Substrate

A polyimide film (trade name: KAPTON 500H, manufactured by DuPont-Toray Co., Ltd., thickness: 128 μm) was used as the organic resin substrate. An epoxy resin layer having a thickness of 5 μm was formed by applying the following epoxy resin composition C on the substrate with a coating bar, and then drying the same at 70° C. for 2 hours.

Epoxy Resin Composition C

| | |
|---|---|
| (A) Epoxy resin (trade name, EPIKOTE 828, | 10 parts by mass |
| manufactured by Japan Epoxy Resins Co., Ltd.) | |
| (B) Low temperature-curable latent curing agent | 2 parts by mass |
| (compound obtained in Synthesis Example 2) | |
| (C) Trimethylol propane trimethacrylate (manufactured | 3 parts by mass |
| by Wako Pure Chemical Industries, Ltd.) | |

Formation of Adhesive Layer

An adhesive layer was formed on the substrate obtained in the above process from composition for adhesive layer B, in a similar manner to Example 7.

Formation of Metal Layer

A multilayer structure having a metal layer formed from a copper foil was obtained by laminating a rolled copper foil having a thickness of 18 μm (manufactured by Nippon Foil Mfg. Co., Ltd.) to the adhesive layer obtained in the above process with a pressure of 0.2 MPa at 80° C.

Electroplating

Multilayer structure O was obtained by forming a copper electroplating layer having a thickness of 8 μm on the above multilayer structure by performing electroless plating at a current density of 3 A/dm² for 20 minutes in an electroplating bath having the following composition, and then performing after-baking at 60° C. for 120 minutes.

Composition of electroplating bath

| | | |
|---|---|---|
| Distilled water | 1300 | mL |
| Copper sulfate pentahydrate (manufactured | 133 | g |
| by Wako Pure Chemical Industries, Ltd.) | | |
| Concentrated sulfuric acid (manufactured by | 340 | g |
| Wako Pure Chemical Industries, Ltd.) | | |
| Hydrochloric acid (manufactured by Wako | 0.25 | mL |
| Pure Chemical Industries, Ltd.) | | |
| COPPER GLEAM PCM (trade name, | 9 | mL |
| manufactured by Meltex Inc.) | | |

Peel strength of the metal layer of the multilayer structures B to 0 obtained in Examples 2 to 15 and multilayer structures CA and CB obtained in Comparative Examples 1 and 2 was measured in a similar manner to Example 1. The results are shown in Table 2.

Further, in Examples 1 to 15 and Comparative Examples 1 and 2, the temperature that is necessary for the adhesive layer to adhere to the metal layer at an interface thereof was measured and determined as a process maximum temperature. The results are shown in Table 2. In Examples 6, 7 and 14 in which a polyimide cast method was employed, the high temperature that is necessary to form a polyimide film by imidization is excluded.

TABLE 2

| | | | | Process | |
|---|---|---|---|---|---|
| | | | | maximum | Peel |
| | Multilayer | | Metal layer | temperature | strength |
| | structure | Substrate | formation process | (° C.) | (kN/m) |
| Example 1 | A | Polyimide | Laminating | 80 | 0.8 |
| Example 2 | B | Polyimide | Laminating | 80 | 0.8 |
| Example 3 | C | Polyimide | Laminating | 80 | 0.8 |
| Example 4 | D | Polyimide/epoxy | Laminating | 80 | 0.8 |
| Example 5 | E | Polyimide/epoxy | Laminating | 80 | 0.9 |
| Example 6 | F | Polyimide | Casting | 60 | 0.8 |
| Example 7 | G | Polyimide | Casting | 60 | 0.9 |
| Example 8 | H | Glass epoxy | Laminating | 80 | 0.9 |
| Example 9 | I | PET | Laminating | 80 | 1.0 |
| Example 10 | J | PEN | Sputtering | 90 | 0.9 |
| Example 11 | K | PC | Sputtering | 90 | 0.9 |
| Example 12 | L | ABS | Sputtering | 90 | 0.9 |
| Example 13 | M | Polyimide/epoxy | Laminating | 80 | 0.8 |
| Example 14 | N | Polyimide | Casting | 60 | 0.9 |
| Example 15 | O | Polyimide/epoxy | Sputtering/plating | 90 | 0.7 |
| Com. Ex. 1 | CA | Polyimide | Laminating | 80 | 0.2 |
| Com. Ex. 2 | CB | Polyimide | Laminating | 80 | 0.1 |

As shown in Table 2, according to the method of producing a multilayer structure of the invention, a metal layer that exhibits a high degree of adhesiveness to the substrate at a process temperature of 90° C. or less can be obtained.

### Example 16

A fine wiring pattern was formed on multilayer structure E obtained in Example 5 by a subtractive method.

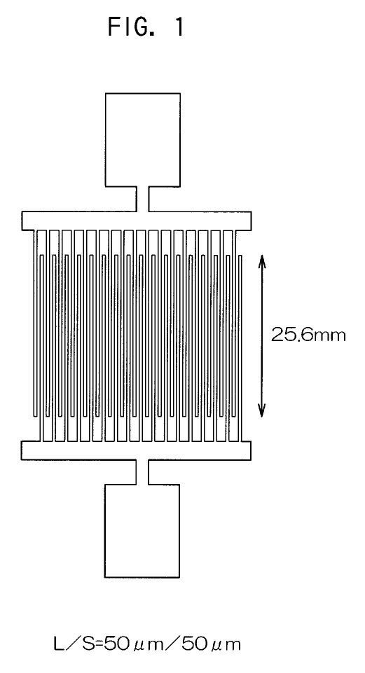

Specifically, a metal pattern (comb-shaped pattern for evaluating insulation property, as shown in FIG. 1) was formed on the surface of metal layer of multilayer structure E obtained in Example 5 by laminating a photo-curable photosensitive dry film (manufactured by Fujifilm Corporation); exposing the same to light via a mask film having a desired conductive circuit pattern (with an opening portion corresponding to the metal pattern and a mask portion corresponding to the non-metal pattern) to print an image; and then developing the image.

Subsequently, the metal film on a portion from which the resist had been removed was removed by an etching solution containing copper chloride. Thereafter, the dry film was peeled off and a copper fine pattern was obtained.

The electric insulating property of the obtained pattern was measured by a HAST tester (trade name: EHS-411M, manufactured by Espec Corp.) at an applied voltage of 10.0 V, a temperature of 125° C. and a humidity of 85% unsaturated (2 atmospheres). As a result, no insulation defects among the wirings (teeth of the comb) were observed.

The test was performed for 200 hours using distilled water having a resistance of 13 MΩ as humidifying water. Thereafter, the failure rate was calculated from the number of damaged wirings that affects the insulating property between the wirings of the comb-shaped pattern.

### Example 17

A fine wiring pattern was formed on multilayer structure E obtained in Example 5 by a semi-additive method.

Specifically, a metal pattern was formed on the surface of metal layer of multilayer structure E obtained in Example 5 by laminating a photo-curable photosensitive dry film (manufactured by Fujifilm Corporation); exposing the same to light via a mask film having a desired conductive circuit pattern (with a mask portion corresponding to the metal pattern and an opening portion corresponding to the non-metal pattern) to print an image; and then developing the image.

Subsequently, electroplating was performed to a portion from which the resist had been removed for 20 minutes in an electroplating bath having the following composition. Thereafter, the dry film resist was peeled off and then the metal layer on a portion on which the metal pattern was not formed was removed using an etching solution containing copper chloride, and a copper fine pattern was obtained. The obtained metal pattern had the same shape as that of Example 16, and the evaluation for insulating property of the metal pattern was conducted in the same manner as Example 16.

Composition of electroplating bath

| | | |
|---|---|---|
| Distilled water | 1300 | mL |
| Copper sulfate pentahydrate (manufactured by | 133 | g |
| Wako Pure Chemical Industries, Ltd.) | | |
| Concentrated sulfuric acid (manufactured by | 340 | g |
| Wako Pure Chemical Industries, Ltd.) | | |
| Hydrochloric acid (manufactured by Wako | 0.25 | mL |
| Pure Chemical Industries, Ltd.) | | |
| COPPER GLEAM PCM (trade name, | 9 | mL |
| manufactured by Meltex Inc.) | | |

### Comparative Example 3

A multilayer structure was prepared by performing copper electroplating on a polyimide film in accordance with a method described in Example 1 of JP-A No. 2004-79660 (non-sputtering plating method employing a surface plasma treatment). A fine pattern was formed on this multilayer structure by a subtractive method as described in Example 16. The insulating property of the obtained pattern was conducted in the same manner as Example 16.

The results of evaluation of Example 16, Example 17 and Comparative Example 3 are shown in the following Table 3.

TABLE 3

| | Sample number | Number of | Failure ratio in |
|---|---|---|---|
| | (number of wiring of | damaged | insulation property |
| | comb-shaped pattern) | wiring | evaluation |
| Example 16 | 30 | 0 | 0% |
| Example 17 | 28 | 0 | 0% |
| Com. Ex. 3 | 28 | 8 | 28.60% |

As shown in Table 3, since the surface of the substrate does not need to be subjected to a pre-treatment for hydrophilizing in the method of the invention, a fine wiring pattern having an excellent electric insulating property can be produced. Further, as shown in Examples 16 and 17, the method of the invention can provide a chromium free process, and thus the impact on environment can be reduced.

<Cross Hatch Test>

The fine wiring pattern (metal pattern) obtained in Examples 16 and 17 and the following Comparative Examples 4 and 5 was cross-cut in a width of 1 mm using a cross cut guide to produce 100 samples (size of each sample: 1 mm×50 μm). Thereafter, tape peeling was performed in accordance with JIS K 5400 (grid test) and the number of samples that remained without being peeled off was examined with a loupe. The results are shown in Table 4. The larger the number of remaining samples in 100 samples (i.e., a numerator), the more the adhesiveness of the pattern with respect to the substrate is.

### Comparative Example 4

Multilayer structure CC was prepared in a similar manner to Example 5, except that acrylic resin E was used instead of acrylic resin A. A fine wiring pattern was formed on this substrate by a subtractive method in the same manner as Example 16.

### Comparative Example 5

Multilayer structure CD was prepared in a similar manner to Example 5, except that acrylic resin E was used instead of acrylic resin A. A fine wiring pattern was formed on this substrate by a semi-additive method in the same manner as Example 17.

TABLE 4

| | Sample peeling test |
|---|---|
| Example 16 | 100/100 |
| Example 17 | 100/100 |
| Com. Ex. 4 | 5/100 |
| Com. Ex. 5 | 5/100 |

As shown in Table 4, the multilayer structure produced by the method of the invention has a metal film (metal pattern) that exhibits excellent adhesiveness to the substrate.

All publications, patent applications, and technical standards mentioned in this specification are herein incorporated by reference to the same extent as if each individual publication, patent application, or technical standard was specifically and individually indicated to be incorporated by reference.

What is claimed is:

1. A method of producing a multilayer structure including a substrate, an adhesive layer and a metal layer, the method comprising:
(a1) forming the adhesive layer on the substrate by applying a composition to the substrate, the composition comprising an acrylic resin having a repeating unit that is derived from an ethylenic unsaturated monomer having a divalent sulfur atom, and applying energy to the composition; and
(b1) forming the metal layer on the adhesive layer by laminating a metal foil or by forming a metal film by evaporation or sputtering.

2. The method according to claim 1, further comprising performing electroless plating or electroplating using the metal layer as a plating nucleus.

3. The method according to claim 1, wherein the composition further comprises a compound that cures upon application of heat or light.

4. The method according to claim 1, wherein the acrylic resin includes a component that cures upon application of heat or light.

5. The method according to claim 1, wherein the composition further comprises a photo-polymerization initiator.

6. The method according to claim 1, wherein the substrate comprises a metal, an organic resin, or a multilayer structure including an organic resin and a metal.

7. The method according to claim 6, wherein the metal layer comprises silver, copper or gold.

8. The method according to claim 7, wherein the metal layer comprises copper.

9. The method according to claim 1, wherein the metal layer is formed in a patterned manner.

10. The method according to claim 6, wherein the organic resin comprises a resin selected from the group consisting of epoxy resin, polyimide resin, polyester resin, polycarbonate resin, and ABS resin.

11. A method of producing a multilayer structure including a substrate, an adhesive layer and a metal layer, the method comprising:
(a2) forming the adhesive layer on a metal foil that forms the metal layer by applying a composition to the metal foil, the composition comprising an acrylic resin having a repeating unit that is derived from an ethylenic unsaturated monomer having a divalent sulfur atom, and applying energy to the composition; and
(b2) forming the substrate on the adhesive layer by forming a film of an organic resin by a casting method.

12. The method according to claim 11, wherein the composition further comprises a compound that cures upon application of heat or light.

13. The method according to claim 11, wherein the acrylic resin includes a component that cures upon application of heat or light.

14. The method according to claim 11, wherein the composition further comprises a photo-polymerization initiator.

15. The method according to claim 11, wherein the metal foil is selected from the group consisting of a copper foil, a tin foil, a lead foil, a tin-lead alloy foil, a nickel foil, a silver foil or an indium foil.

16. The method according to claim 15, wherein the metal foil is a copper foil.

17. The method according to claim 11, wherein the metal layer is formed in a patterned manner.

18. The method according to claim 11, wherein the organic resin comprises a resin selected from the group consisting of epoxy resin, polyimide resin, polyester resin, polycarbonate resin, and ABS resin.
